(19) United States
(12) Patent Application Publication
(10) Pub. No.: US 2025/0043046 A1
(43) Pub. Date: Feb. 6, 2025

(54) POLYMER, COMPOSITION INCLUDING THE SAME, AND METHOD OF FORMING PATTERN USING THE COMPOSITION

(71) Applicant: Samsung Electronics Co., Ltd., Suwon-si (KR)

(72) Inventors: Minsang KIM, Suwon-si (KR); Haengdeog KOH, Suwon-si (KR); Yoonhyun KWAK, Suwon-si (KR); Jeongho MUN, Hwaseong-si (KR); Seonghyeon AHN, Suwon-si (KR); Chanjae AHN, Suwon-si (KR); Jaejun LEE, Suwon-si (KR); Kyuhyun IM, Suwon-si (KR); Jungha CHAE, Suwon-si (KR); Sungwon CHOI, Suwon-si (KR)

(73) Assignee: Samsung Electronics Co., Ltd., Suwon-si (KR)

(21) Appl. No.: 18/405,175

(22) Filed: Jan. 5, 2024

(30) Foreign Application Priority Data
Aug. 4, 2023 (KR) 10-2023-0102277

(51) Int. Cl. C08F 120/28; G03F 7/004; G03F 7/20

(52) U.S. Cl. CPC C08F 120/28; G03F 7/0045; G03F 7/0048; G03F 7/2016

(57) ABSTRACT

Provided are a polymer including a first repeating unit represented by Formula 1 and having a glass transition temperature of 50° C. or less, a polymer-containing composition including the polymer, and a method of forming a pattern by using the polymer-containing composition:

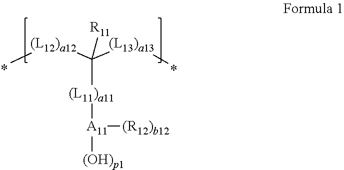

wherein, in Formula 1,
descriptions of L₁₁ to L₁₃, a11 to a13, An, R₁₁, R₁₂, b12, and p1 are provided in the present specification.

### CROSS-REFERENCE TO RELATED APPLICATION

This application is based on and claims priority under 35 U.S.C. § 119 to Korean Patent Application No. 10-2023-0102277, filed on Aug. 4, 2023, in the Korean Intellectual Property Office, the disclosure of which is incorporated by reference herein in its entirety.

### BACKGROUND

### 1. Field

The disclosure relates to a polymer, a polymer-containing composition including the same, and a method of forming a pattern by using the composition.

### 2. Description of the Related Art

In recent years, with the rapid spread of information media, the capabilities of semiconductor devices have also advanced rapidly. In the case of recent semiconductor products, high integration of product is required for low cost and high quality to secure competitiveness.

Meanwhile, as the degree of integration of semiconductor devices increases, the distance between wires may decrease, and an etching process is required to effectively form a plurality of wires spaced apart from each other.

Accordingly, there is a need for materials that have improved gap-fill properties, thereby preventing and/or reducing voids and/or seams, and that can be quickly removed while still acting as a protective barrier in subsequent processes.

### SUMMARY

Provided are a polymer having improved resistance to wet etching, improved etching speed for dry etching, and/or improved gap-fill properties, a polymer-containing composition including the polymer, and a method of forming a pattern by using the polymer-containing composition.

Additional aspects will be set forth in part in the description which follows and, in part, will be apparent from the description, or may be learned by practice of the presented embodiments of the disclosure.

According to an aspect of the disclosure, a polymer includes a first repeating unit represented by Formula 1 and has a glass transition temperature of 50° C. or less:

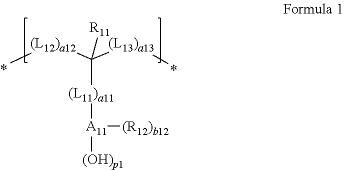

wherein, in Formula 1,
L₁₁ to L₁₃ may each independently be a single bond, O, S, C(═O), C(═O)O, OC(═O), C(═O)NH, NHC(═O), or a linear, branched, or cyclic C₁-C₃₀ divalent hydrocarbon group that optionally includes a heteroatom,
a11 to a13 may each independently be an integer from 1 to 4,
A₁₁ may be a linear, branched, or cyclic C₁-C₃₀ alkyl group that optionally includes a heteroatom, or a linear, branched, or cyclic C₁-C₃₀ alkenyl group that optionally includes a heteroatom,
R₁₁ and R₁₂ may each independently be hydrogen, deuterium, a halogen, a cyano group, a hydroxy group, an amino group, a carboxylic acid group, a thiol group, an ester moiety, a sulfonate ester moiety, a carbonate moiety, a lactone moiety, a sultone moiety, a carboxylic anhydride moiety, or a linear, branched, or cyclic C₁-C₃₀ monovalent hydrocarbon group that optionally includes a heteroatom,
b12 may be an integer from 1 to 10,
p1 may be an integer from 1 to 5, and
* indicates a binding site to a neighboring atom.

According to another aspect of the disclosure, a polymer-containing composition includes the polymer, an acid generator, and an organic solvent.

According to another aspect of the disclosure, a method of forming a pattern includes forming an insulating layer by applying the polymer-containing composition onto a substrate provided with a first layer, forming an insulating pattern exposing a first surface of the first layer by selectively removing at least a portion of the insulating layer, and removing the first layer having the exposed first surface.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a pattern formation method according to at least one embodiment;

FIGS. 2A to 2C are each a side cross-sectional view illustrating a pattern formation method according to at least one embodiment; and

FIGS. 3A to 3D are each a side cross-sectional view illustrating a method of preparing a semiconductor device according to at least one embodiment.

### DETAILED DESCRIPTION

Reference will now be made in detail to embodiments, examples of which are illustrated in the accompanying drawings, wherein like reference numerals refer to like elements throughout.

In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The disclosure may undergo various modifications and may have various embodiments. Accordingly, specific embodiments are illustrated in the drawings and described in detail in the detailed description. However, this is not intended to limit the disclosure to a specific embodiment, and should be understood to include all modifications, equivalents, or substitutes included in the spirit and technical scope of the disclosure. In describing the disclosure, when it is determined that a detailed description of related known technologies may make the gist of the disclosure unclear, the detailed description will be omitted.

The terms “first”, “second”, “third”, etc., may be used to describe various elements, but are used only for the purpose of distinguishing one element from another element, and the order or type of the elements are not limited.

Throughout this specification, a portion of a layer, film, region, plate, etc., described as being “on” or “above” another portion thereof may be positioned directly above, below, to the left or right of, while in contact, as well as above, below, to the left or light of, while in a non-contact.

Singular expressions include plural expressions unless the context clearly dictates otherwise. Terms such as “include” or “have” are intended to indicate the presence of features, numbers, steps, operations, elements, parts, components, materials, or combinations thereof described in the specification unless otherwise stated, and it should be understood that the terms do not preclude the possibility of the presence or addition of one or more other features, numbers, steps, operations, elements, parts, components, materials, or combinations thereof.

Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values. Whenever a range of values is recited, that range includes all values that fall within that range, as if explicitly written out, and further includes the boundaries of the range. Thus, the range of “X to Y” includes all values between X and Y, and also includes X and Y.

The term “Cₓ-C_{y}” used herein refers to a case where the number of carbons constituting the substituent is x to y. For example, “C₁-C₆” refers to a case where the number of carbons constituting the substituent is 1 to 6, and “C₆-C₂₀” refers to a case where the number of carbons constituting the substituent is 6 to 20.

The term “monovalent hydrocarbon group” as used herein refers to a monovalent residue derived from an organic compound including carbon and hydrogen or a derivative of the organic compound, and examples thereof may include: a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cyclic aliphatic hydrocarbon group (e.g., a cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclotricyclodecanyl group, a tetracyclododecanyl group, a tetracyclododecanylmethyl group, and a dicyclohexylmethyl group); a monovalent unsaturated aliphatic hydrocarbon group (e.g., an alkenyl group, an alkynyl group, and an allyl group); a monovalent unsaturated cyclic aliphatic hydrocarbon group (e.g., a cycloalkenyl group and a 3-cyclohexenyl group); an aryl group (e.g., a phenyl group, a 1-napthyl group, and a 2-napthyl group); an arylalkyl group (e.g., a benzyl group and a diphenylmethyl group); a heteroatom-containing monovalent hydrocarbon group (e.g., a tetrahydrofuranyl group, a methoxymethyl group, an ethoxy methyl group, a methylthiomethyl group, an acetamidemethyl group, a trifluoroethyl group, a (2-methoxyethoxy)methyl group, an acetoxymethyl group, a 2-carboxyl-1-cyclohexyl group, a 2-oxopropyl group, a 4-oxo-1-adamantyl group, and a 3-oxocyclohexyl group); or any combination thereof. Some hydrogens in these groups may be replaced by moieties containing heteroatoms such as oxygen, sulfur, nitrogen, or halogen atoms, or some carbons in these groups may be substituted by moieties containing heteroatoms such as oxygen, sulfur, or nitrogen. Accordingly, these groups may include hydroxy groups, cyano groups, carbonyl groups, carboxyl groups, ether linkages, ester linkages, ester sulfate linkages, carbonates, lactone rings, sultone rings, carboxylic acid anhydride moieties or haloalkyl moieties.

The term “divalent hydrocarbon group” as used herein refers to a divalent residue in which one hydrogen of the monovalent hydrocarbon group is replaced by a binding site to a neighboring atom. Examples of the divalent hydrocarbon group may include a linear or branched alkylene group, a cycloalkylene group, an alkenylene group, an alkynylene group, a cycloalkylene group, an arylene group, or a group in which some carbon atoms are replaced by a heteroatom.

The term “alkyl group” used herein refers to a linear or branched saturated aliphatic hydrocarbon monovalent group, and examples thereof include a methyl group, an ethyl group, a propyl group, an isobutyl group, a sec-butyl group, a ter-butyl group, a pentyl group, an iso-amyl group, a hexyl group, and/or the like. The term “alkylene group” as used herein refers to a linear or branched saturated aliphatic divalent hydrocarbon group, and examples thereof may include a methylene group, an ethylene group, a propylene group, a butylene group, an isobutyl group, and/or the like.

The term “halogenated alkyl group” as used herein refers to a group in which one or more hydrogen atoms of an alkyl group are substituted with halogen, and examples include may include CF₃ and/or the like.

The term “alkoxy group” used herein refers to a monovalent group represented by —OA₁₀₁, where A₁₀₁ is an alkyl group and O is oxygen. Examples thereof include a methoxy group, an ethoxy group, an isopropyloxy group, and/or the like.

The term “alkylthio group” as used herein refers to a monovalent group represented by —SA₁₀₁, wherein A₁₀₁ is an alkyl group and S is sulfur.

The term “halogenated alkyl group” as used herein refers to a group in which one or more hydrogen atoms of an alkoxy group are substituted with halogen, and examples thereof may include —OCF₃ and/or the like.

The term “halogenated alkylthio group” as used herein refers to a group in which one or more hydrogen atoms of an alkylthio group are substituted with halogen, and examples thereof may include —SCF₃ and/or the like.

The term “cycloalkyl group” used herein refers to a monovalent saturated hydrocarbon cyclic group, and examples thereof include monocyclic groups such as a cyclopropyl group, a cyclobutyl group, a cyclopentyl group, a cyclohexyl group, a cycloheptyl group, and/or the like, and polycyclic condensed cyclic groups such as a norbornyl group and an adamantyl group. The term “cycloalkylene group” used herein refers to a divalent saturated hydrocarbon cyclic group, and examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and/or the like.

The term “cycloalkoxy group” used herein refers to a monovalent group represented by —OA₁₀₂, where A₁₀₂ is a cycloalkyl group. Examples thereof include a cyclopropoxy group, a cyclobutoxy group, and/or the like.

The term “cycloalkylthio group” as used herein refers to a monovalent group represented by —SA₁₀₂, wherein A₁₀₂ is a cycloalkyl group.

The term “heterocycloalkyl group” used herein refers to a group in which some carbon atoms of the cycloalkyl group are replaced by a moiety including a heteroatom, such as oxygen, sulfur, or nitrogen, and examples of the heterocycloalkyl group include an ether linking group, an ester linking group, a sulfonic ester linking group, a carbonate, a lactone ring, a sultone ring, or a carboxylic anhydride moiety. The term “heterocycloalkylene group” used herein refers to a group in which some carbon atoms of the cycloalkylene group are replaced by a moiety including a heteroatom, such as oxygen, sulfur, or nitrogen.

The term “heterocycloalkoxy group” as used herein refers to a monovalent group represented by —OA₁₀₃, wherein A₁₀₃ is a heterocycloalkyl group.

The term “alkenyl group” as used herein refers to a linear or branched unsaturated aliphatic monovalent hydrocarbon including one or more carbon-carbon double bond. The term “alkenylene group” as used herein refers to a linear or branched unsaturated aliphatic divalent hydrocarbon including one or more carbon-carbon double bonds.

The term “alkenyloxy group” as used herein refers to a monovalent group represented by —OA₁₀₄, wherein A₁₀₄ is an alkenyl group.

The term “cycloalkenyl group” as used herein refers to a monovalent unsaturated cyclic hydrocarbon group including one or more carbon-carbon double bonds. The term “cycloalkenylene group” as used herein refers to a divalent unsaturated cyclic hydrocarbon group including one or more carbon-carbon double bonds.

The term “cycloalkenyloxy group” as used herein refers to a monovalent group represented by —OA₁₀₅, wherein A₁₀₅ is an alkenyl group.

The term “heterocycloalkenyl group” as used herein refers to a group in which some carbon atoms of the cycloalkenylene group are replaced by a moiety including a heteroatom, such as oxygen, sulfur, or nitrogen. The term “heterocycloalkenylene group” used herein refers to a group in which some carbon atoms of the cycloalkenylene group are replaced by a moiety including a heteroatom, such as oxygen, sulfur, or nitrogen.

The term “heterocycloalkenyloxy group” as used herein refers to a monovalent group represented by —OA₁₀₆, wherein A₁₀₆ is a heterocycloalkenyl group.

The term “alkynyl group” as used herein refers to a linear or branched unsaturated aliphatic monovalent hydrocarbon including one or more carbon-carbon triple bonds.

The term “alkynyloxy group” as used herein refers to a monovalent group represented by —OA₁₀₇, wherein A₁₀₇ is an alkenyl group.

The term “aryl group” used herein refers to a monovalent group having a carbocyclic aromatic system, and examples include a phenyl group, a naphthyl group, an anthracenyl group, a phenanthrenyl group, a pyrenyl group, and a chrysenyl group.

The term “aryloxy group” as used herein refers to a monovalent group represented by —OA₁₀₈, wherein A₁₀₈ is an alkyl group.

The term “heteroaryl group” used herein refers to a monovalent group having a heterocyclic aromatic system, and examples thereof include a pyridinyl group, a pyrimidinyl group, a pyrazinyl group, and/or the like. The term “heteroarylene group” used herein refers to a divalent group having a heterocyclic aromatic system.

The term “heteroaryloxy group” as used herein refers to a monovalent group represented by —OA₁₀₉, wherein A₁₀₉ is a heteroaryl group.

The term “substituent” as used herein may include: deuterium, a halogen, a hydroxyl group, a cyano group, a nitro group, a carbonyl group, a carboxylic acid group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group;
a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group, each substituted with deuterium, a halogen, a hydroxyl group, a cyano group, a nitro group, a carbonyl group, a carboxylic acid group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, or any combination thereof; and any combination thereof.

Hereinafter, at least one embodiment will be described in detail with reference to the drawings, and in the description with reference to the drawings, substantially the same or corresponding elements are denoted with the same reference numerals, and overlapping descriptions thereof will be omitted. Regarding the drawings, the thickness is shown enlarged to clearly express the various layers and regions. Also, in the drawings, the thicknesses of some layers and regions are exaggerated for convenience of description. On the other hand, the embodiments described below are merely illustrative, and various modifications can be made on these embodiments.

### [Polymer]

A polymer according to some embodiments includes a first repeating unit represented by Formula 1 and has a glass transition temperature of 50° C. or less:

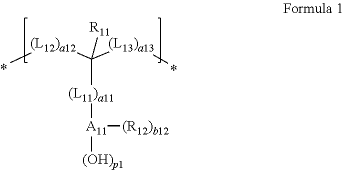

wherein, in Formula 1:
L₁₁ to L₁₃ may each independently be a single bond; O; S; C(═O); C(═O)O; OC(═O); C(═O)NH; NHC(═O); or a linear, branched, or cyclic C₁-C₃₀ divalent hydrocarbon group that optionally includes a heteroatom,
a11 to a13 may each independently be an integer from 1 to 4,
A₁₁ may be a linear, branched, or cyclic C₁-C₃₀ alkyl group that optionally includes a heteroatom; or a linear, branched, or cyclic C₁-C₃₀ alkenyl group that optionally includes a heteroatom,
R₁₁ and R₁₂ may each independently be hydrogen; deuterium; a halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group that optionally includes a heteroatom,
b12 may be an integer from 1 to 10,
p1 may be an integer from 1 to 5, and
* indicates a binding site to a neighboring atom.

In at least one embodiment, the glass transition temperature of the polymer may be 25° C. or less. Here, the glass transition temperature is a value obtained by measurement, and an example measuring method is as described in further detail with the Examples below.

In at least one embodiment, L₁₁ to L₁₃ in Formula 1 may each independently be a single bond; O; S; C(═O); C(═O)O; OC(═O); C(═O)NH; NHC(═O); a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

In at least one embodiment, L₁₁ to L₁₃ in Formula 1 may each independently be selected from a single bond; O; C(═O); C(═O)O; OC(═O); or a C₁-C₂₀ alkylene group, a C₃-C₂₀ cycloalkylene group, a C₃-C₂₀ heterocycloalkylene group, a C₂-C₂₀ alkenylene group, a C₃-C₂₀ cycloalkenylene group, a C₃-C₂₀ heterocycloalkenylene group, a C₆-C₂₀ arylene group, or a C₁-C₂₀ heteroarylene group, each unsubstituted or substituted with deuterium, a halogen, a cyano group, a hydroxy group, an amino group, a carboxylic acid group, a thiol group, an ester moiety, a sulfonate ester moiety, a carbonate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

In at least one embodiment, L₁₁ to L₁₃ in Formula 1 may each independently be selected from as a single bond; O; C(═O); C(═O)O; OC(═O); or a C₁-C₂₀ alkylene group, a C₃-C₂₀ cycloalkylene group, a C₃-C₂₀ heterocycloalkylene group, a phenylene group, or a naphthylene group, each unsubstituted or substituted with deuterium, a halogen, a C₁-C₂₀ alkyl group, a C₁-C₂₀ halogenated alkyl group, a C₁-C₂₀ alkoxy group, a phenyl group, a naphthyl group, or any combination thereof.

In at least one embodiment, L₁₁ in Formula 1 may be selected from a single bond; O; C(═O); C(═O)O; or OC(═O).

In at least one embodiment, L₁₂ and L₁₃ in Formula 1 may each independently be selected from: a single bond; O; C(═O); C(═O)O; OC(═O); or a C₁-C₂₀ alkylene group unsubstituted or substituted with deuterium, a halogen, a C₁-C₂₀ alkyl group, a C₁-C₂₀ halogenated alkyl group, a C₁-C₂₀ alkoxy group, a phenyl group, a naphthyl group, or any combination thereof.

In Formula 1, a11 to a13 represent the number of repeats of L₁₁ to the number of repeats of L₁₃, respectively.

In at least one embodiment, a11 to a13 in Formula 1 may each independently be an integer from 1 to 3.

In at least one embodiment, a11 to a13 in Formula 1 may each independently be 1.

In at least one embodiment, An in Formula 1 may be a linear, branched, or cyclic C₁-C₃₀ alkyl group that optionally includes a heteroatom.

In at least one embodiment, An in Formula 1 may be selected from: groups represented by Formulae 9-1 to 9-37 and 10-1 to 10-48; groups in which at least one carbon of one of the groups represented by Formulae 9-1 to 9-37 and 10-1 to 10-48 is substituted with oxygen; and groups in which at least one carbon of one of the groups represented by Formulae 9-1 to 9-37 and 10-1 to 10-48 is substituted with a carbonyl group:

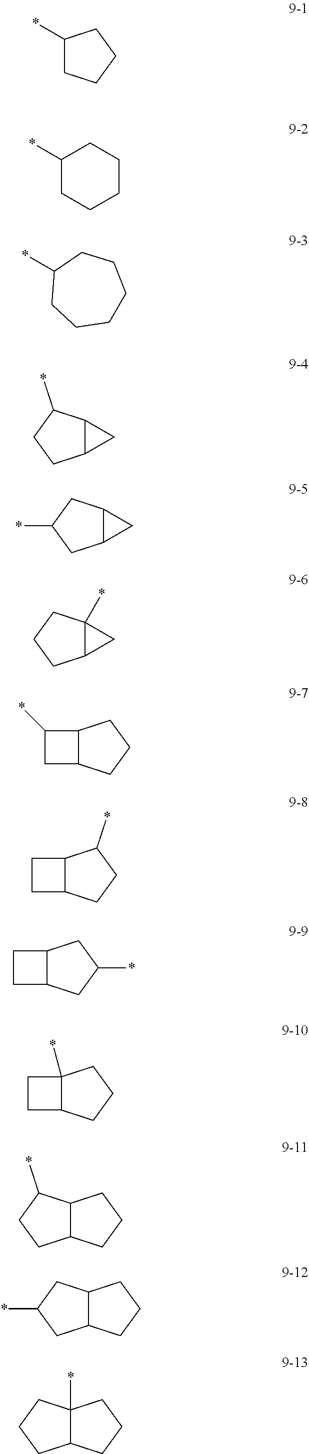

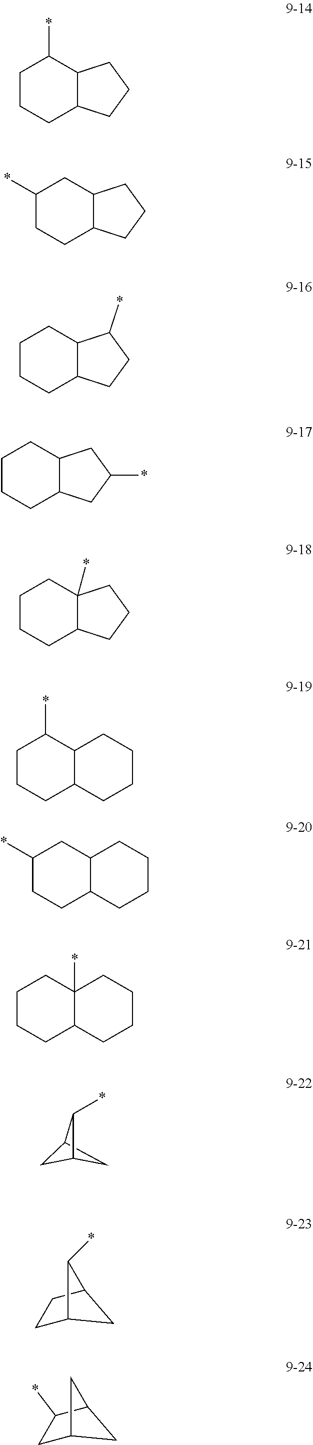

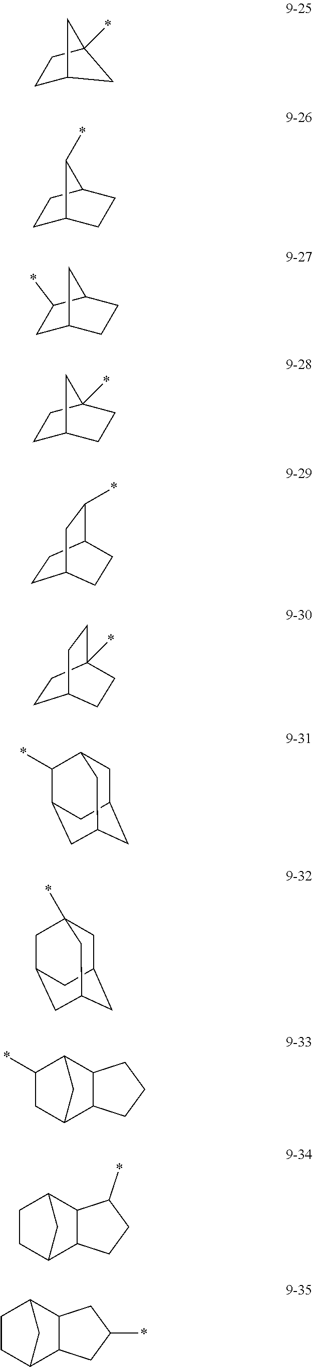

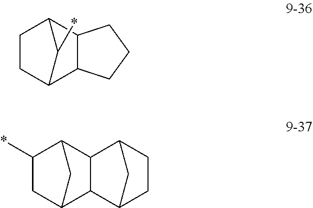

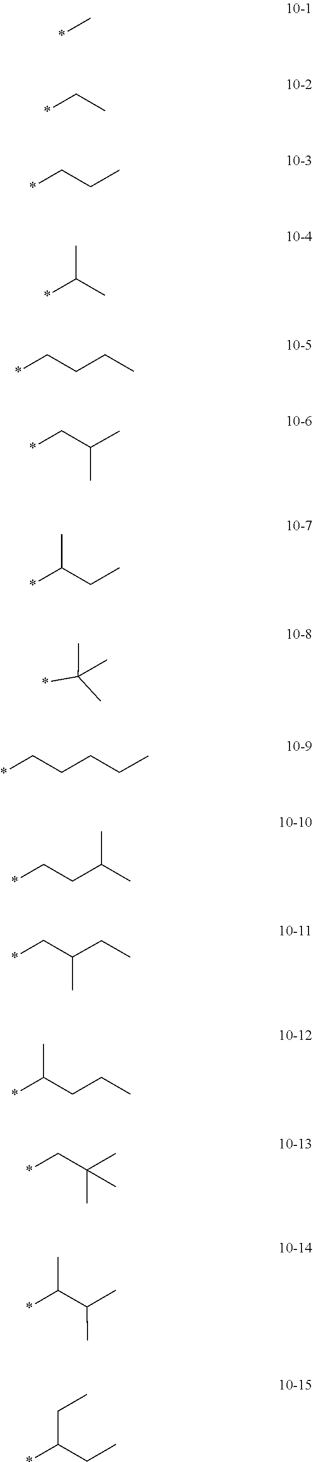

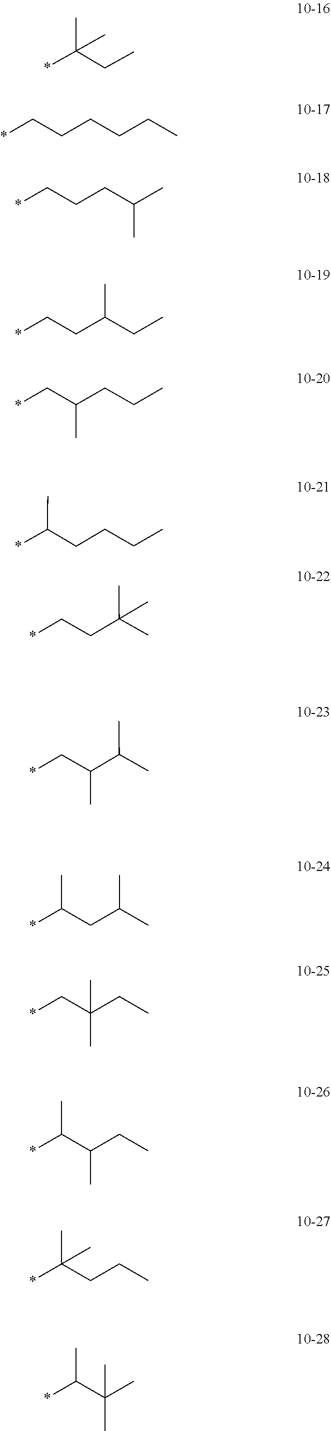

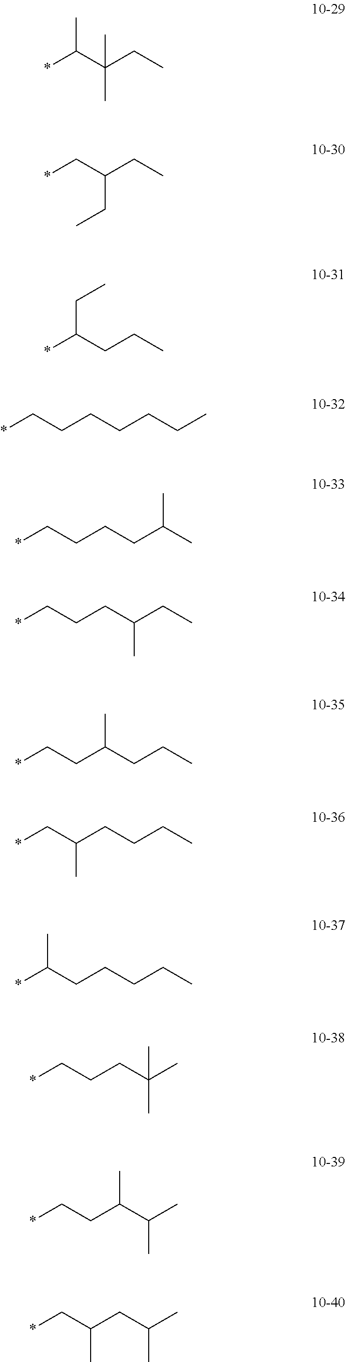

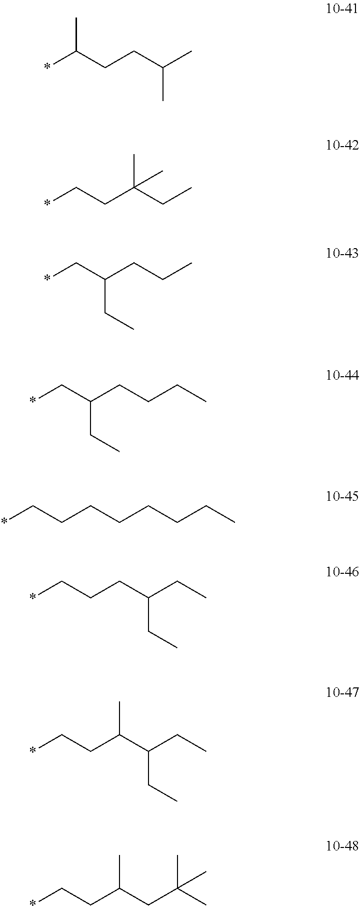

wherein, in Formulae 9-1 to 9-37 and 10-1 to 10-48,
* indicates a binding site to L₁₁.

In Formulae 9-1 to 9-37 and 10-1 to 10-48, a number (e.g., p1) of the hydrogens may each be substituted with OH, and the remaining hydrogens may each be substituted with R₁₂.

In at least one embodiment, A₁₁ in Formula 1 may be selected from the groups represented by Formulae 10-1 to 10-48.

In at least one embodiment, R₁₁ and R₁₂ in Formula 1 may each independently be selected from hydrogen; deuterium; a halogen; a cyano group; a hydroxy group; an amino group; a carboxylic acid group; a thiol group; or a C₁-C₂₀ alkyl group, a C₃-C₂₀ cycloalkyl group, or a C₆-C₂₀ aryl group, each unsubstituted or substituted with deuterium, a halogen, a cyano group, a hydroxy group, an amino group, a carboxylic acid group, a thiol group, an ester moiety, a sulfonate ester moiety, a carbonate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

In at least one embodiment, R₁₁ in Formula 1 may be hydrogen, deuterium, a halogen, CH₃, CH₂F, CHF₂, CF₃, CH₂CH₃, CHFCH₃, CHFCH₂F, CHFCHF₂, CHFCF₃, CF₂CH₃, CF₂CH₂F, CF₂CHF₂, or CF₂CF₃.

In at least one embodiment, R₁₂ in Formula 1 may be hydrogen; deuterium; a halogen; a cyano group; a hydroxy group; an amino group; a carboxylic acid group; a thiol group; a C₁-C₂₀ alkyl group; a C₁-C₂₀ halogenated alkyl group; a C₃-C₂₀ cycloalkyl group; or a C₆-C₂₀ aryl group.

In at least one embodiment, the first repeating unit may be represented by Formula 1-1:

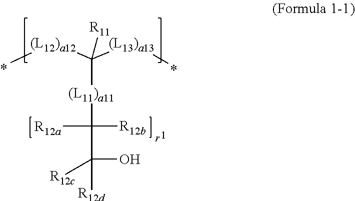

wherein, in Formula 1-1,
L₁₁ to L₁₃, a11 to a13, and R₁₁ may each be as defined in Formula 1,
r1 may be an integer from 1 to 3,
R₁₂ₐ to R_{12d} may each be defined the same as R₁₂ in Formula 1, and
* indicates a binding site to a neighboring atom.

In at least one embodiment, the first repeating unit may be selected from Group I:

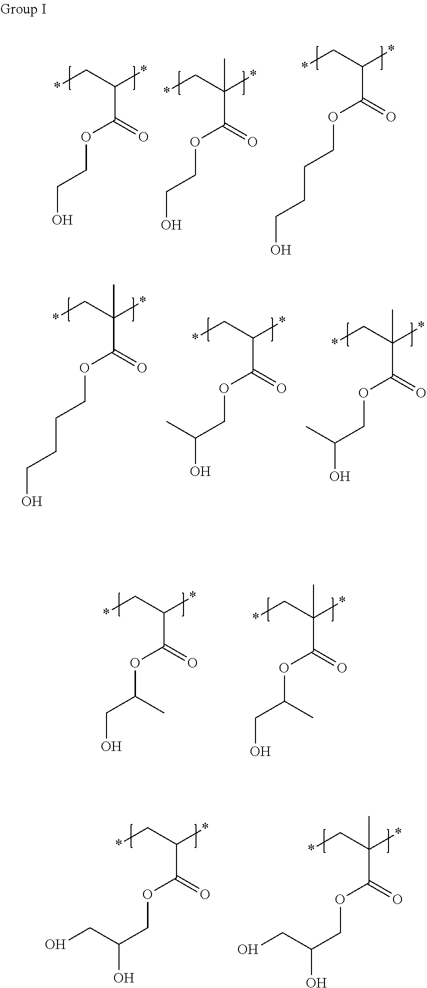

In one or more embodiments, the polymer may further include at least one of a second repeating unit represented by Formula 2 and a third repeating unit represented by Formula 3:

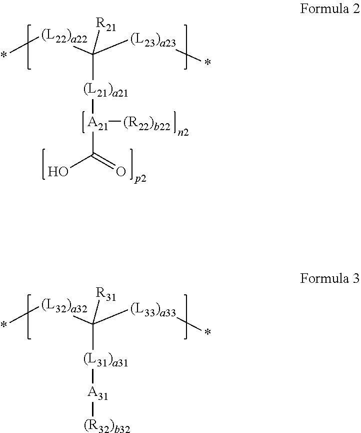

wherein, in Formulae 2 and 3,
L₂₁ to L₂₃ and L₃₁ to L₃₃ may each independently be a single bond; O; S; C(═O); C(═O)O; OC(═O); C(═O)NH; NHC(═O); or a linear, branched, or cyclic C₁-C₃₀ divalent hydrocarbon group that optionally includes a heteroatom,
a21 to a23 and a31 to a33 may each independently be an integer from 1 to 4,
A₂₁ and A₃₁ may each independently be a linear, branched, or cyclic C₁-C₃₀ alkyl group that optionally includes a heteroatom; a linear, branched, or cyclic C₁-C₃₀ alkenyl group that optionally includes a heteroatom; or a C₁-C₃₀ aromatic group that optionally includes a heteroatom,
n2 may be 0 or 1,
R₂₁, R₂₂, R₃₁, and R₃₂ may each independently be hydrogen; deuterium; a halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group that optionally includes a heteroatom,
b22 and b32 may each independently be an integer from 1 to 10,
p2 may be an integer from 1 to 5, and
* indicates a binding site to a neighboring atom.

In at least one embodiment, L₂₁ to L₂₃ and L₃₁ to L₃₃ in Formulae 2 and 3 may each independently be as defined in Ln. For example, the groups from which L₂₁ to L₂₃ and L₃₁ to L₃₃ are selected may be the same and/or substantially similar to the groups from which L₁₁ are selected.

In at least one embodiment, a21 to a23 and a31 to a33 in Formulae 2 and 3 may each independently be as defined with respect to all. For example, a21 to a23 and a31 to a33 may each independently be an integer from 1 to 4.

The groups from which A₂₁ to A₂₃ and A₃₁ to A₃₃ are selected may be the same and/or substantially similar to the groups from which A₁₁ are selected. For example, in at least one embodiment, in Formulae 2 and 3, A₂₁ and A₃₁ may each independently be: a linear, branched, or cyclic C₁-C₃₀ alkyl group that optionally includes a heteroatom; or a C₁-C₃₀ aromatic group that optionally includes a heteroatom.

In at least one embodiment, in Formulae 2 and 3, A₂₁ and A₃₁ may each independently be selected from groups represented by Formulae 9-1 to 9-37 and 10-1 to 10-48; a group in which at least one carbon of one of the groups represented by Formulae 9-1 to 9-37 and 10-1 to 10-48 is substituted with oxygen; a group in which at least one carbon of one of the groups represented by Formulae 9-1 to 9-37 and 10-1 to 10-48 is substituted with a carbonyl group; a benzene group; a naphthalene group; a phenanthrene group; and an anthracene group:

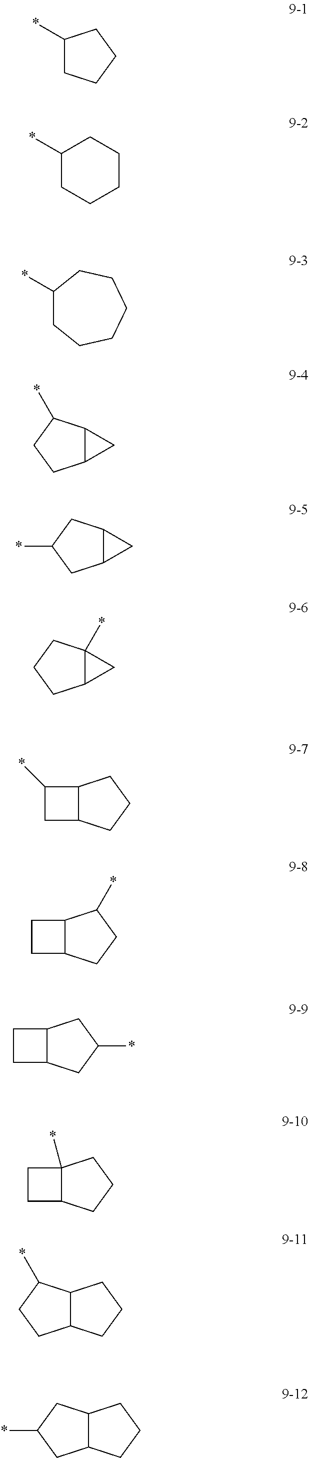

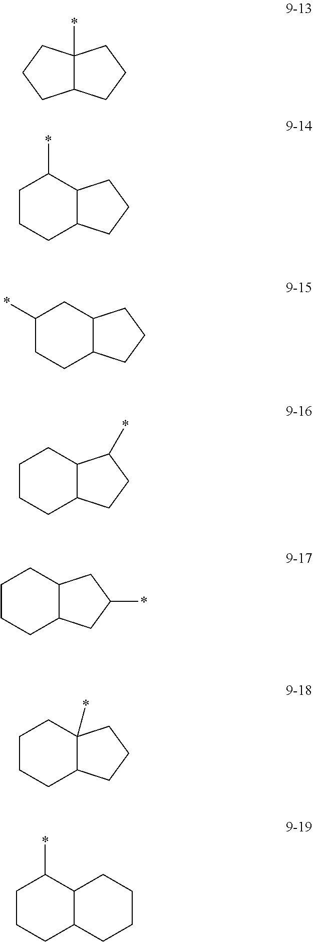

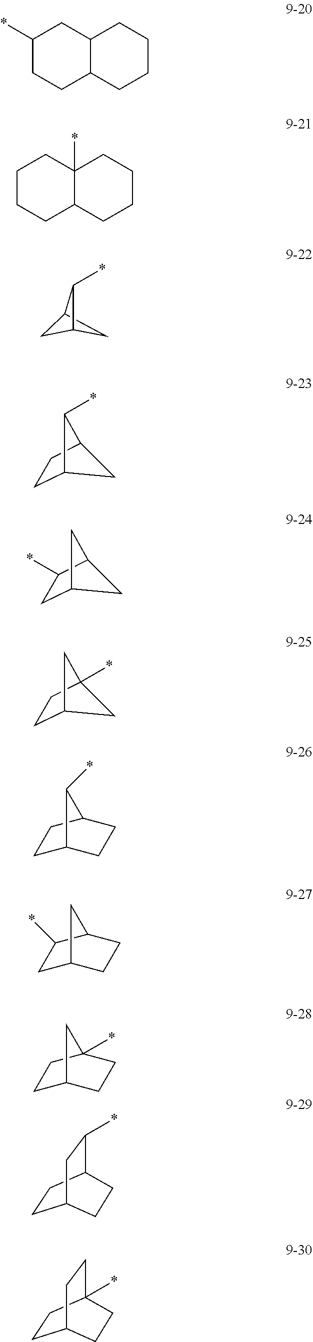

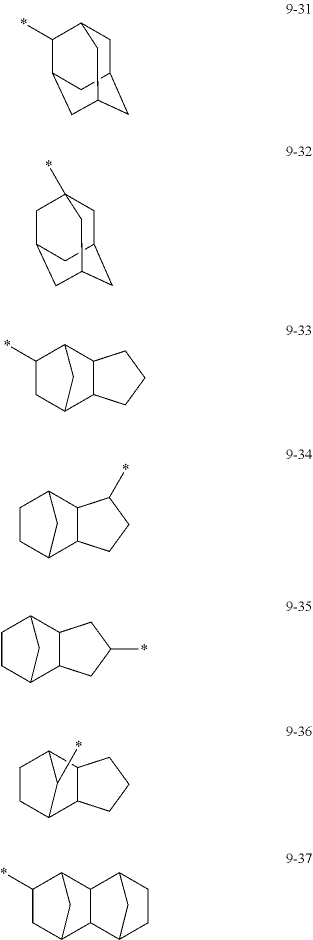

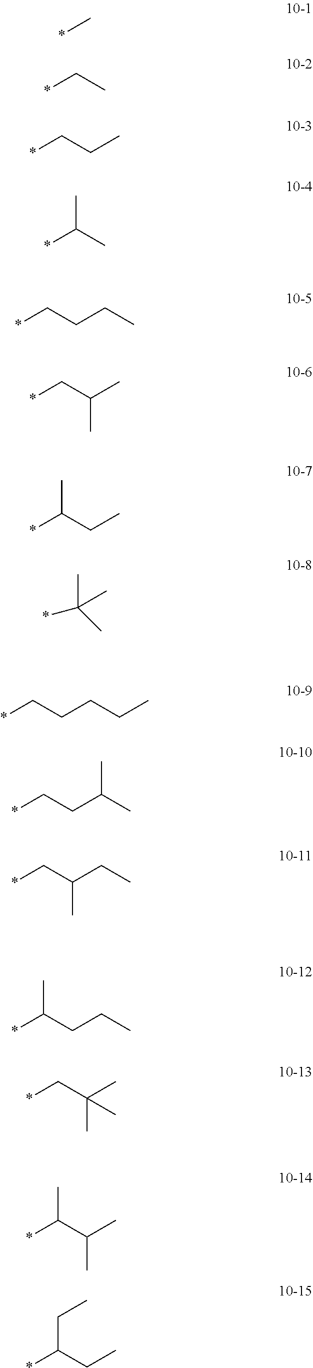

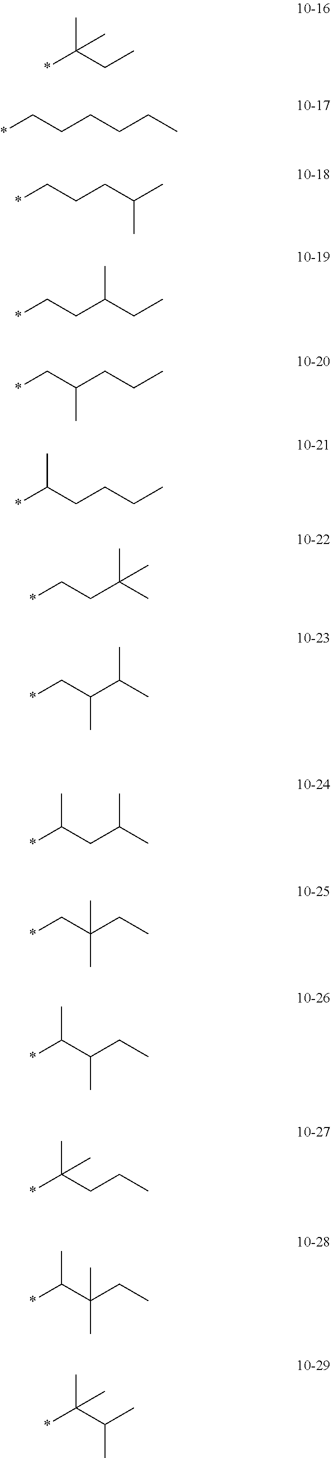

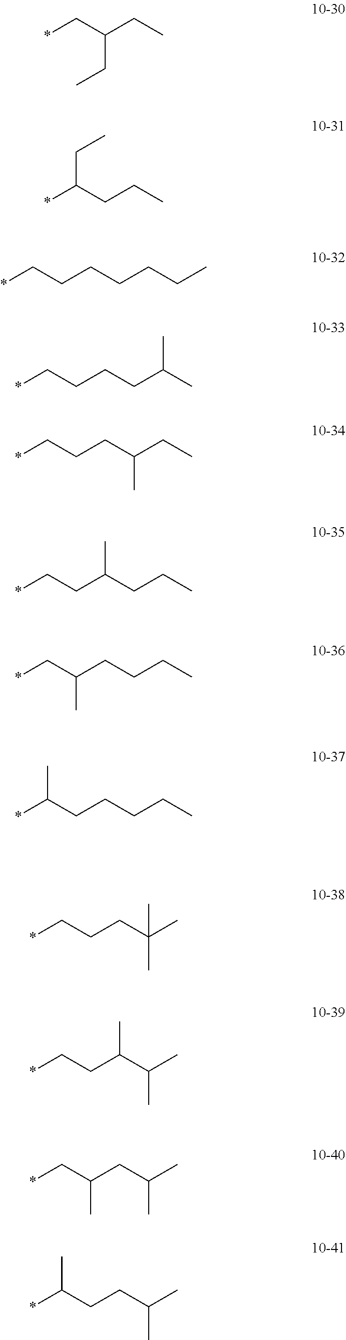

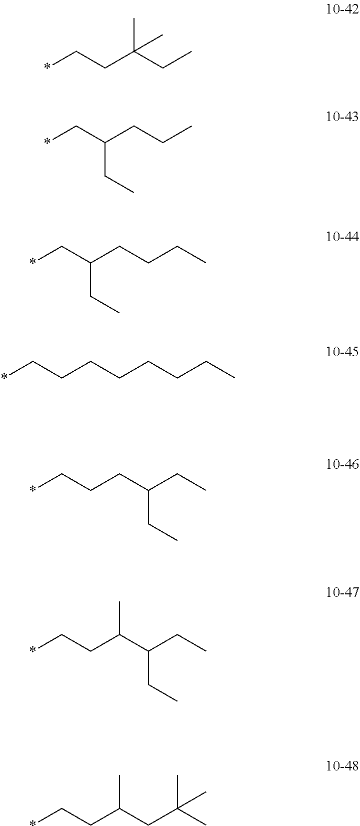

wherein, in Formulae 9-1 to 9-37 and 10-1 to 10-48,
* indicates a binding site to L₂₁ or L₃₁.

In Formulae 9-1 to 9-37 and 10-1 to 10-48 of Formula 2 and Formula 3, a number (e.g., p2) of hydrogens may each be substituted with COOH, and the remaining hydrogens may each be substituted with R₂₂.

In at least one embodiment, R₂₁, R₂₂, R₃₁, and R₃₂ in Formulae 2 and 3 may each independently be as defined in R₁₁.

In at least one embodiment, R₃₂ in Formula 3 may be a linear, branched, or cyclic C₁-C₃₀ monovalent hydrocarbon group that optionally includes a heteroatom.

In at least one embodiment, the second repeating unit may be represented by one of or two or more selected from Group II:

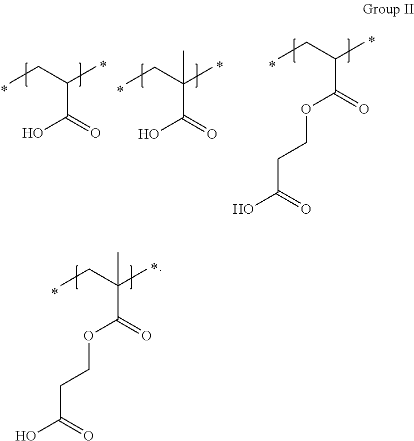

In at least one embodiment, the third repeating unit may be represented by one of or two or more selected from Group III:

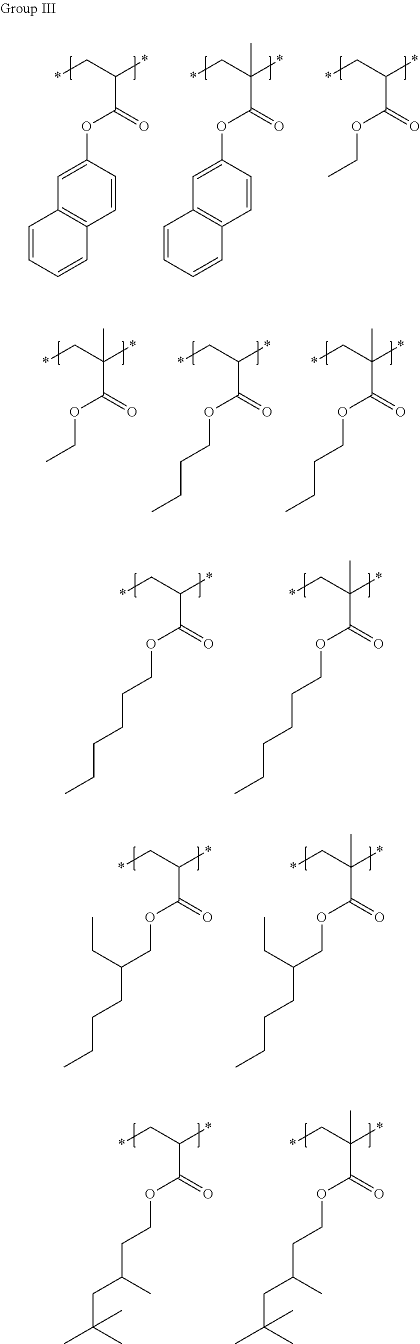

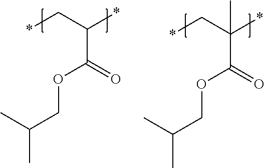

In at least one embodiment, the polymer may include the first repeating unit in an amount in a range of about 1 mol % to about 100 mol %, about 5 mol % to about 100 mol %, and about 10 mol % to about 100 mol %.

In one or more embodiments, the polymer chain may consist of the first repeating unit.

In one or more embodiments, the polymer may include the second repeating unit in an amount in a range of about 0 mol % to about 99 mol %, about 1 mol % to about 99 mol %, and about 10 mol % to about 90 mol %.

In one or more embodiments, the polymer may include the third repeating unit in an amount in a range of about 0 mol % to about 99 mol %, about 1 mol % to about 99 mol %, and about 10 mol % to about 90 mol %.

In one or more embodiments, the polymer may comprise a polymer chain consisting of the first repeating unit and the second repeating unit. For example, in at least one embodiment, the polymer chains of the polymer may consist of copolymers of the first repeating unit and the second repeating unit. In one or more embodiments, the polymer may include the first repeating unit in an amount in a range of about 1 mol % to about 99 mol % or about 10 mol % to about 90 mol %, and the second repeating unit in an amount in a range of about 1 mol % to about 99 mol % or about 10 mol % to about 90 mol %.

In one or more embodiments, the polymer may comprise a polymer chain consisting of the first repeating unit and the third repeating unit. For example, in at least one embodiment, the polymer chains of the polymer may consist of copolymers of the first repeating unit and the third repeating unit. In one or more embodiments, the polymer may include the first repeating unit in an amount in a range of about 1 mol % to about 99 mol % or about 10 mol % to about 90 mol %, and the third repeating unit in an amount in a range of about 1 mol % to about 99 mol % or about 10 mol % to about 90 mol %.

In one or more embodiments, the polymer may include a polymer chain consisting of the first repeating unit, the second repeating unit, and the third repeating unit. For example, in at least one embodiment, the polymer chains of the polymer may consist of copolymers of the first repeating unit, the second repeating unit, and the third repeating unit. In one or more embodiments, the polymer may include the first repeating unit in an amount in a range of about 1 mol % to about 98 mol % or about 5 mol % to about 90 mol %, the second repeating unit in an amount in a range of about 1 mol % to about 98 mol % or about 5 mol % to about 90 mol %, and the third repeating unit in an amount in a range of about 1 mol % to about 98 mol % or about 5 mol % to about 90 mol %.

The polymer may have a weight average molecular weight (Mw) in a range of about 1,000 to 100,000, for example, about 2,000 to about 80,000, and/or about 3,000 to about 50,000, wherein the weight average molecular weight Mw is measured by gel permeation chromatography using tetrahydrofuran as a solvent and polystyrene as a standard material.

In at least one embodiment, the polymer may consist of: the first repeating unit; or the first repeating unit and the second repeating unit, wherein the polymer may have a weight average molecular weight Mw in a range of about 3,000 to about 10,000.

The polymer may have polydispersity index (PDJ: Mw/Mn) in a range of about 1.0 to about 3.0, for example, about 1.0 to about 2.5. Within these ranges, the possibility of foreign matters remaining on the pattern may be lowered, or deterioration of a pattern profile may be minimized. Accordingly, the polymer-containing composition may be suitable for forming fine patterns.

The structure (composition) of the polymer may be confirmed by performing Fourier transform infrared (FT-IR) analysis, nuclear magnetic resonance (NMR) analysis, X-ray fluorescence (XRF) analysis, mass spectrometry, ultraviolet UV analysis, single crystal X-ray structure analysis, powder X-ray diffraction (PXRD) analysis, liquid chromatography (LC) analysis, size exclusion chromatography (SEC) analysis, thermal analysis, and/or the like. An example confirmation method is as described in detail with the Examples below.

Since the polymer including the first repeating unit represented by Formula 1 includes one or more OH groups, the adhesion to a lower film, e.g., a lower film including an inorganic material, may be improved.

Also, the polymer including the first repeating unit represented by Formula 1 may undergo a crosslinking reaction, e.g., an esterification reaction and/or an etherification reaction, when forming a film, and such a cross-linked product may have relatively high resistant to a wet etching process.

Furthermore, since the polymer including the first repeating unit represented by Formula 1 has a relatively low glass transition temperature, the polymer may have improved gap-fill properties.

When the polymer including the first repeating unit represented by Formula 1 further includes the second repeating unit represented by Formula 2, the adhesion to a lower film including the inorganic material may be improved and/or the etching speed in a dry etching process may be accelerated.

When the polymer including the first repeating unit represented by Formula 1 further includes the second repeating unit represented by Formula 3, the density of the polymer may be increased, and accordingly, the swelling of a film formed by the polymer to an etchant may be reduced.

### [Polymer-Containing Composition]

Another aspect of the disclosure provides a polymer-containing composition that includes the polymer, an acid generator, and an organic solvent.

As the polymer including the repeating unit represented by Formula 1 and being used in the polymer-including composition, one type of the polymer or a combination of two or more different types of the polymer may be used.

The polymer may be included in an amount of about 0.1 parts by weight to about 50 parts by weight based on 100 parts by weight of the polymer-containing composition.

Specifically, the polymer may be included in an amount of about 0.5 parts by weight to about 30 parts by weight based on 100 parts by weight of the polymer-containing composition. When the amount of the polymer is satisfied within the ranges above, any performance loss, such as degradation in film-forming properties and/or reduction in formation of foreign particles due to a lack of solubility, may be reduced.

The polymer-containing composition may not include a cross-linking agent. Even if the polymer-containing composition does not include a cross-linking agent, when the polymer-containing composition is applied and heated or exposed, a crosslinking reaction, e.g., an esterification reaction and/or an etherification reaction, in which the acid generator may act as a catalyst may occur.

The polymer is as defined above, and the acid generator, the organic solvent, and additional components such as a surfactant included as necessary will be described below.

### <Acid Generator>

The acid generator may be selected to promote the crosslinking reaction of the polymer-containing composition.

The acid generator may be configured to generate acid by light and/or heat.

The acid generator may be, for example, a photoacid generator, and/or a thermal acid generator. In at least one embodiment, the acid generator may include p-toluenesulfonic acid, trifluoromethanesulfonic acid, pyridinium-p-toluenesulfonate, pyridinium trifluoromethanesulfonate, salicylic acid, 5-sulfosalicylic acid, camphorsulfonic acid, 4-chlorobenzenesulfonic acid, 4-phenolsulfonic acid, 4-phenolsulfonate methyl, benzenedisulfonic acid, 1-naphthalenesulfonic acid, citric acid, benzoic acid, hydroxybenzoic acid, or any combination thereof.

The acid generator may be included in an amount in a range of about 0.01 parts by weight to about 40 parts by weight, about 0.1 parts by weight to about 40 parts by weight, or about 0.1 parts by weight to about 20 parts by weight, based on 100 parts by weight of the polymer.

One type of the acid generator may be used, or a combination of two or more different types of the acid generator may be used.

### <Organic Solvent>

The organic solvent included in the polymer-containing composition may be selected based on the organic solvents capability to dissolve and/or disperse the polymer, acid generator, and additional components contained as necessary.

Examples of the organic solvent may include an alcohol-based solvent, an ether-based solvent, a ketone-based solvent, an amide-based solvent, an ester-based solvent, a sulfoxide-based solvent, a hydrocarbon-based solvent, and/or the like.

Examples of the alcohol-based solvent may include a monoalcohol-based solvent (such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexane alcohol, 3,3,5-trimethylcyclohexanol, benzyl alcohol, diacetone alcohol, and/or the like); a polyhydric alcohol solvent (such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, and tripropylene glycol; and polyhydric alcohol-containing ether solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, and/or the like.

Examples of the ether-based solvent may include a dialkylether-based solvent (such as diethylether, dipropylether, dibutylether, diethylene glycol dimethylether, dipropyleneglycol dimethylether, and/or the like); a cyclic ether-based solvent (such as tetrahydrofuran, tetrahydropyran, and/or the like); and an aromatic ring-containing ether-based solvent (such as diphenylether, anisole, and/or the like).

Examples of the ketone-based solvent may include a chain ketone solvent (such as acetone, methylethylketone, methyl-n-propyl ketone, methyl-n-butyl ketone, methyl-n-pentyl ketone, diethyl ketone, methyl isobutyl ketone, 2-heptanone, ethyl-n-butyl ketone, methyl-n-hexyl ketone, diisobutyl ketone, trimethyl nonanone, and/or the like); a cyclic ketone-based solvent (such as cyclopentanone, cyclohexanone, cycloheptanone, cyclooctanone, methylcyclohexanone, and/or the like); 2,4-pentandione; acetonyl acetone; acetphenone; and/or the like.

Examples of the amide-based solvent may include a cyclic amide-based solvent (such as N,N′-dimethylimidazolidinone, N-methyl-2-pyrrolidone, and/or the like); a chain amide-based solvent (such as N-methylformamide, N,N-dimethylformamide, N,N-diethylformamide, acetamide, N-methylacetamide, N,N-dimethylacetamide, N-methylpropionamide, and/or the like); and/or the like.

Examples of the ester-based solvent may include an acetate ester solvent (such as methyl acetate, ethyl acetate, n-propyl acetate, isopropyl acetate, n-butyl acetate, isobutyl acetate, sec-butyl acetate, T-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, and/or the like); a polyhydric alcohol-containing ether carboxylate solvent (such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, and/or the like); a lactone solvent (such as γ-butyrolactone and δ-valerolactone; carbonate solvents such as dimethyl carbonate, diethyl carbonate, ethylene carbonate, and propylene carbonate; lactate ester solvents such as methyl lactate, ethyl lactate, n-butyl lactate, n-amyl lactate, and/or the like); glycoldiacetate; methoxytriglycol acetate; ethyl propionate; n-butyl propionate; isoamyl propionate; diethyloxalate; di-n-butyloxalate; methyl acetoacetate; ethyl acetoacetate; diethyl malonate; dimethyl phthalate; diethyl phthalate; and/or the like.

Examples of the sulfoxide-based solvent may include dimethyl sulfoxide, diethyl sulfoxide, and/or the like.

Examples of the hydrocarbon-based solvent include aliphatic hydrocarbon-based solvents (such as n-pentane, isopentane, n-hexane, isohexane, n-heptane, isoheptane, 2,2,4-trimethylpentane, n-octane, isooctane, cyclohexane, methylcyclohexane, and/or the like); and aromatic hydrocarbon-based solvents (such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, n-amylnaphthalene, and/or the like).

In at least one embodiment, the organic solvent may be selected from an alcohol-based solvent, an amide-based solvent, an ester-based solvent, a sulfoxide-based solvent, and/or any combination thereof. In one or more embodiments, the organic solvent may be selected from propylene glycol monomethyl ether, propylene glycol monoethyl ether, propylene glycol monomethyl ether acetate, N-methyl-2-pyrrolidone, N,N-dimethylacetamide, ethyl lactate, dimethyl sulfoxide, and/or any combination thereof.

In at least one embodiment, when an acid labile group (e.g., in the form of acetal) is used, the organic solvent may further include high-boiling alcohol (such as diethylene glycol, propylene glycol, glycerol, 1,4-butanediol, 1,3-butanediol, and/or the like), in order to accelerate the deprotection reaction of acetal.

One type of the organic solvent may be used, or a combination of two or more different types of the organic solvent may be used.

The organic solvent may be used in an amount in a range of about 200 parts by weight to about 20,000 parts by weight, for example, about 2,000 to about 10,000 parts by weight, based on 100 parts by weight of the polymer.

### <Additional Components>

The polymer-containing composition may further include a surfactant, an additive, or any combination thereof, as needed.

The polymer-containing composition may further include a surfactant to improve coating properties and/or the like. Examples of the surfactant may include a non-ionic surfactant (such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, polyethylene glycol distearate, and/or the like); and/or the like. For use as the surfactant, a commercially available product may be used, or a synthetic product may be used.

Examples of the commercially available product may include KP341 (manufactured by Shin-Etsu Chemical Co., Ltd.), POLYFLOW No. 75 and POLYFLOW No. 95 (manufactured by Kyoeisha Chemical Co., Ltd.), FTOP EF301, FTOP EF303, and FTOP EF352 (manufactured by Mitsubishi Materials Electronic Chemicals Co., Ltd.), MEGAFACE F171 (registered trademark), MEGAFACE F173, R40, R41, and R43 (manufactured by DIC Corporation), Fluorad FC430 (registered trademark) and Fluorad FC431 (manufactured by 3M Company), AsahiGuard AG710 (product of AGC Corporation), Surflon 5-382 (registered trademark), Surflon SC-101, Surflon SC-102, Surflon SC-103, Surflon SC-104, Surflon SC-105, and Surflon SC-106 (manufactured by AGC Seimi Chemical Co., Ltd.), and/or the like.

The surfactant may be included in an amount in a range of about 0 parts by weight to about 20 parts by weight based on 100 parts by weight of the polymer.

One type of the surfactant may be used, or a combination of two or more different types of the surfactant may be used.

The polymer-containing composition may further include an additive to improve the adhesion to a substrate onto which the polymer-containing composition is applied and to prevent a film formed of the polymer-containing composition from peeling off at an undesired time. Examples of the additive may include aromatic hydroxy compounds, such as phenol, cresol, xylenol, pyrocatechol, resorcinol, hydroquinone, pyrogallol, 1,2,4-benzenetriol, salicyl alcohol, p-hydroxybenzyl alcohol, p-hydroxyphenethyl alcohol, p-aminophenol, m-aminophenol, diaminophenol, aminoresorcinol, p-hydroxybenzoic acid, o-hydroxybenzoic acid, 2,4-dihydroxybenzoic acid, 2,5-dihydroxybenzoic acid, 3,4-dihydroxybenzoic acid, 3,5-dihydroxybenzoic acid, gallic acid, and/or the like. In at least some embodiments the additive to improve adhesion may be selected as additive supporting the adhesion of the —OH of Formula 1.

The additive may be included in an amount in a range of about 0 parts by weight to about 20 parts by weight based on 100 parts by weight of the polymer.

One type of the additive may be used, or a combination of two or more different types of the additive may be used.

A method of preparing the polymer-containing composition is not particularly limited, and for example, a method of mixing a polymer, an acid generator, and optional components added as necessary in an organic solvent may be used. The temperature or time during mixing is not particularly limited. If necessary, filtration may be performed after mixing.

### [Pattern Formation Method]

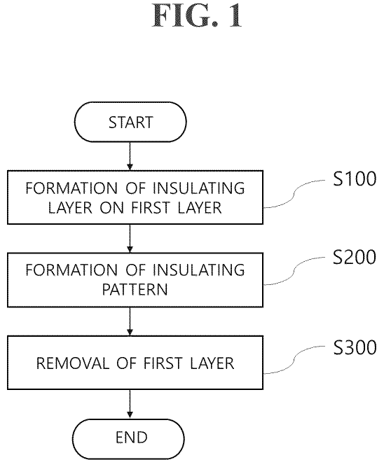

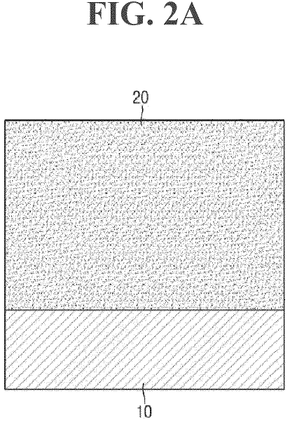

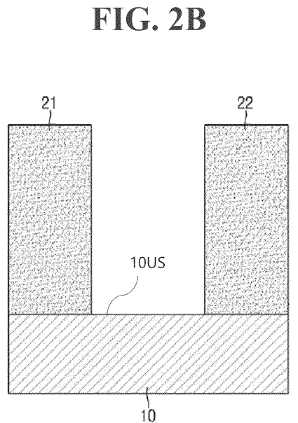

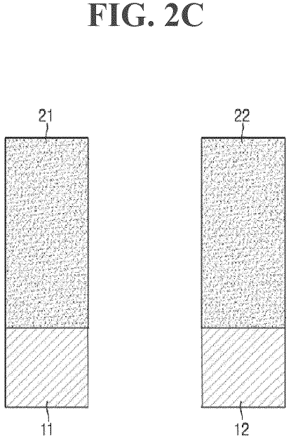

Hereinafter, a pattern formation method according to embodiments will be described in more detail with reference to FIGS. 1 and 2A to 2C. FIG. 1 is a flowchart representing a pattern formation method according to at least one embodiment, and FIGS. 2A to 2C are each a side cross-sectional view illustrating a pattern formation method according to at least one embodiment.

Referring to FIGS. 1 and 2A to 2C, a method of forming a pattern includes: forming an insulating layer by applying the polymer-containing composition onto a substrate provided with a first layer (S100); forming an insulating pattern exposing a first surface of the first layer by selectively removing at least a portion of the insulating layer (S200); and removing the first layer with the exposed first surface exposed (S300).

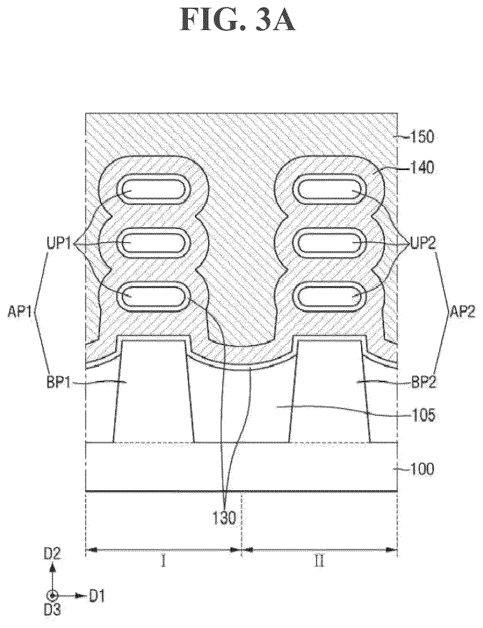

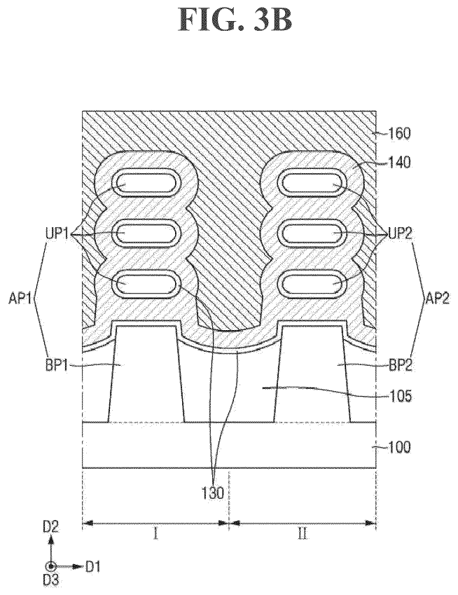

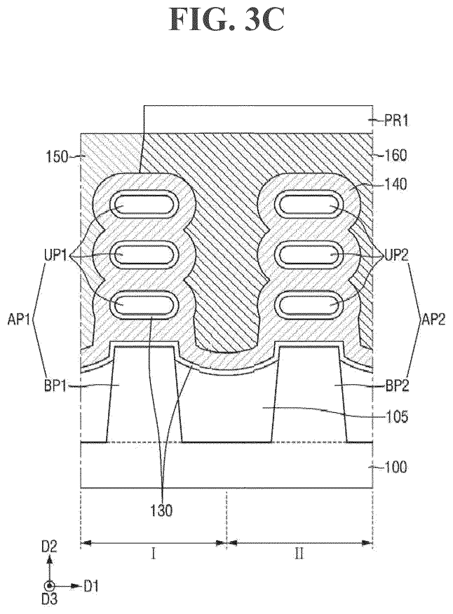

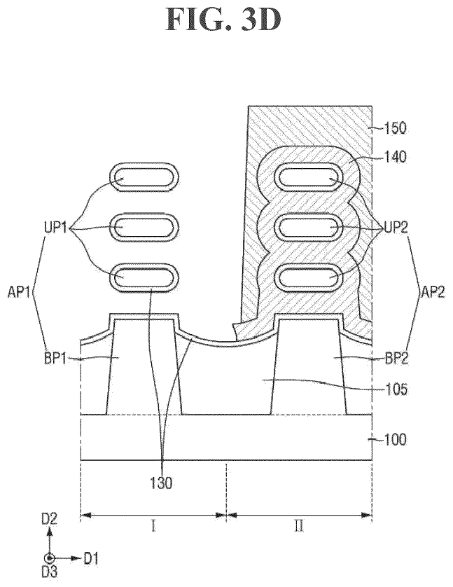

First, a substrate (e.g., 100 of FIG. 3A) is prepared. The substrate may be, for example, a semiconductor substrate, such as a silicon substrate. a germanium substrate, and/or the like, and/or may be include glass, quartz, ceramic, copper, and/or the like. In at least one embodiment, the substrate may include a Group III-V compound, such as GaP, GaAs, GaSb, and/or the like.

A first layer 10 may be provided on the substrate. The first layer 10 may include, for example, conductive metal oxide, conductive metal oxynitride, conductive metal nitride, or any combination thereof. In at least one embodiment, the first layer 10 may include titanium nitride, titanium oxynitride, or any combination thereof. The first layer 10 may further include an organic polymer. The first layer 10 may be formed by, for example, atomic layer deposition (ALD), chemical vapor deposition (CVD), reactive sputtering, ion plating, vacuum deposition, spin coating (e.g., spin on glass (SOG)).

Next, on the substrate provided with the first layer 10, the aforementioned polymer-containing composition may be applied to a desired thickness according to an appropriate coating method to form an insulating layer 20. The insulating layer 20 may be a dry etch resist layer and/or a wet etch resist layer, but the embodiments are not limited thereto.

A thickness of the insulating layer 20 may be, for example, in a range of about 0.001 m to about 10 m, for example, about 0.002 m to about 1 m, and for example, about 0.005 m to about 0.5 m.

Since the polymer-containing composition includes the acid generator, acids may be generated when a stimulus such as light and/or heat is applied, and thus the crosslinking reaction of the polymer-containing composition may be promoted.

Accordingly, when forming the insulating layer 20, the substrate 100 on which the polymer-containing composition is applied may optionally be baked using a heating means such as a hot plate. A lower limit of the baking temperature may be 60° C. or higher, for example, 80° C. or higher. Also, the upper limit of the baking temperature may be 150° C. or lower, for example, 140° C. or lower. When the baking temperature is lower than the ranges above, crosslinks may not be sufficiently formed so that the insulating layer 20 thus formed may not have sufficient resistance to an etchant. When the baking temperature is higher than the ranges above, the insulating layer 20 may be decomposed by heat. A lower limit of the baking time may be 5 seconds or more, for example, 10 seconds or more. An upper limit of the baking time may be 600 seconds or less, for example, 300 seconds or less.

Next, a resist pattern (not shown) may be additionally formed on the insulating layer 20. A resist pattern may be formed through a conventional method, such as a resist pattern formation method including applying of a resist composition, exposure, and development. The resist pattern thus formed may be used as a mask in the forming of the insulating pattern.

Next, at least a portion of the insulating layer 20 may be selectively removed to form an insulating pattern 21 or 22 exposing a first surface (10US) of the first layer 10.

The insulating pattern 21 or 22 may be formed by using a dry etching process, and for example, may be formed by using a dry etching process using the aforementioned resist pattern as a mask. Types of gas used in the dry etching process are not particularly limited, but freon-based gas, oxygen-based gas, and/or nitrogen-based gas may be used.

Next, the first layer 10 having the exposed first surface 10US may be removed by using a wet etching process. Here, the insulating pattern 21 or 22 may be used as a mask. An etchant used in the wet etching process may include hydrogen peroxide. The etchant may further include: a basic substance (such as ammonia, sodium hydroxide, potassium hydroxide, sodium cyanide, potassium cyanide, and/or the like); an organic amine (such as triethanolamine); and/or an acidic substance (e.g., an inorganic acid, such as hydrochloric acid, sulfuric acid, and/or the like).

Next, the insulating pattern 21 or 22 may be removed. The insulating pattern 21 or 22 may be removed by using a wet etching process, an ashing process, or any combination thereof.

The steps may be omitted if necessary, or may be performed in reverse order.

### [Preparation Method of Semiconductor Apparatus]

Hereinafter, a method of preparing a semiconductor apparatus according to some embodiments will be described in detail with reference to FIGS. 3A and 3D.

In the drawings of a semiconductor apparatus to be described below, at least one embodiment depicts a semiconductor apparatus with a gate-all-around transistor, but embodiments are not limited thereto.

In one or more embodiments, the semiconductor apparatus may include field effect transistor (FET), a planar FET, a fin FET, a tunneling FET, or a 3D transistor. In one or more embodiments, the semiconductor apparatus may include a planar transistor without difficulty.

Furthermore, the technical idea of the disclosure may be applied to 2D material-based FETs and heterostructures thereof.

Also, in one or more embodiments, the semiconductor apparatus may include a bipolar junction transistor, a laterally-double diffused metal-oxide transistor, or the like.

Referring to FIG. 3A, the substrate 100 is provided. The substrate 100 may include a first region I and a second region II. The first region I and the second region II may be adjacent to each other, or may be separated from each other.

A first active pattern AP1 may be formed in the first region I of the substrate 100. A second active pattern AP2 may be formed in the second region II of the substrate 100. A portion where the first activity pattern AP1 and the second activity pattern AP2 may be an active region.

The first activity pattern AP1 may have a first bottom pattern BP1 and a plurality of first sheet pattern UP1. The second activity pattern AP2 may have a second bottom pattern BP2 and a plurality of second sheet pattern UP2. The first sheet pattern UP1 and the second sheet pattern UP2 are shown as having three each, but are shown only for convenience of explanation and are not limited thereto.

The first bottom pattern BP1 and the second bottom pattern BP2 may protrude from the substrate 100 in the second direction D2 and extend long in the third direction D3. The first bottom pattern BP1 and the second bottom pattern BP2 may be spaced apart from each other in the first direction (D1). The first direction D1, the second direction D2, and the third direction D3 may intersect each other. The first direction D1, the second direction D2, and the third direction D3 may be substantially perpendicular to each other.

A field insulating film 105 may be formed between the first bottom pattern BP1 and the second bottom pattern BP2. The field insulating film 105 may include, for example, an oxide film, a nitride film, an oxynitride film, or any combination thereof.

A gate insulating film 130 may be then formed. The gate insulating film 130 may be formed on an upper surface of the field insulating film 105, an upper surface and a portion of side surface of the first bottom pattern BP1, an upper surface and a portion of side surface of the second bottom pattern BP2, the first sheet pattern UP1, and the second sheet pattern UP2. The gate insulating film 130 may surround the perimeters of first sheet pattern UP1 and the second sheet pattern UP2. The gate insulating film 130 may include a high dielectric constant material.

A work function metal layer 140 may be formed on the substrate 100. The work function metal layer 140 may be formed on the gate insulating film 130. The work function metal layer 140 may surround the perimeters of the first sheet pattern UP1 and the second sheet pattern UP2. The work function metal layer 140 may include conductive metal oxide, conductive metal oxynitride, conductive metal nitride, or any combination thereof. In at least one embodiment, the work function metal layer 140 may include titanium nitride, titanium oxynitride, or any combination thereof.

A protective layer 150 may be formed on the work function metal layer 140. The protective layer 150 may cover the work function metal layer 140. Materials included in the protective layer 150 may be the same as or similar to those included in the work function metal layer 140. For example, the protective layer 150 may include titanium nitride, but embodiments are not limited thereto.

Referring to FIG. 3B, an insulating layer may be formed on the protective layer 150 by using the aforementioned polymer-containing composition. The protective layer 150 and the insulating layer may be then combined to form a sacrificial layer 160.

Referring to FIG. 3C, a resist pattern PR1 may be formed on the sacrificial layer 160. The resist pattern PR1 may cover the sacrificial layer 160 on the second region II and a portion of the sacrificial layer 160 on the first region I.

Next, the insulating layer within the sacrificial layer 160 may be removed by using the resist pattern PR1 as a mask. By removing the insulating layer within the sacrificial layer 160, the surface of the protective layer 150 may be exposed. The removing of the insulating layer within the sacrificial layer 160 may be performed by a dry etching process, but embodiments are not limited thereto.

Referring to FIG. 3D, in the first region I, the protective layer 150 and the work function metal layer 140 may be removed. Only the protective layer 150 of the first region I may be selectively removed. The removing of the protective layer 150 and the work function metal layer 140 in the first region I may be performed by a wet etching process. When the wet etching process is performed, the protective layer 150 and the work function metal layer 140 may be removed, but the sacrificial layer 160 may not be removed. An etchant used in the wet etching process may not penetrate through the insulating layer. Therefore, the etchant may not reach the sacrificial layer 160 of the second region II, and thus the sacrificial layer 160 of the second region II may not be removed.

Next, the insulating layer within the sacrificial layer 160 of the second region II may be removed to form the protective layer 150. The insulating layer may be removed by using a wet etching process, an ashing process, or any combination thereof, but embodiments are not limited thereto.

The disclosure will be described in more detail using Examples and Comparative Examples, but the technical scope of the disclosure is not limited to the following Examples.

### EXAMPLE

### Synthesis Example 1: Synthesis of Polymer pHEA

Hydroxyethyl acrylate (HEA) (5 g, 0.043 mol) as Monomer 1 and V601 (an azo initiator of C₁₀H₁₈N₂O₂) (0.99 g, 0.0043 mol) were dissolved in propylene glycol monomethylether (PGME) (9.3 g), the and the mixed solution was allowed for a reaction at 80° C. for 4 hours. Next, diethylether was used for precipitation, and the precipitate was dried to form Polymer HEA (pHEA).

### Synthesis Examples 2 to 7

Polymers were obtained in the same manner as in Synthesis Example 1, except that Monomers 1 and 2 of Table 1 were used instead of just Monomer 1. The polymers obtained by Synthesis Examples 1 to 7 were analyzed through ¹H-NMR and gel permeation chromatograpy (GPC), and the weight average molecular weight, PDI, and glass transition temperature (Tg) thereof were measured and results thereof are shown in Table 2. Here, the glass transition temperature Tg was obtained by performing thermal analysis (N₂ atmosphere, temperature interval: at room temperature and up to 600° C. (10° C./min), disposable Al pan) using differential scanning calorimetry (DSC).

TABLE 1

| | | | | Monomer percentage | |
|---|---|---|---|---|---|
| | | Monomer | | (mol %) | |
| | Polymer | Monomer 1 | Monomer 2 | Monomer 1 | Monomer 2 |
| Synthesis Example 1 | pHEA | HEA | — | 100 | — |
| Synthesis Example 2 | pHA10 | HEA | HA | 90 | 10 |
| Synthesis Example 3 | pHA20 | HEA | HA | 80 | 20 |
| Synthesis Example 4 | pHA30 | HEA | HA | 70 | 30 |
| Synthesis Example 5 | pHA40 | HEA | HA | 60 | 40 |
| Synthesis Example 6 | pHA50 | HEA | HA | 50 | 50 |
| Synthesis Example 7 | pHN10 | HEA | HN | 90 | 10 |

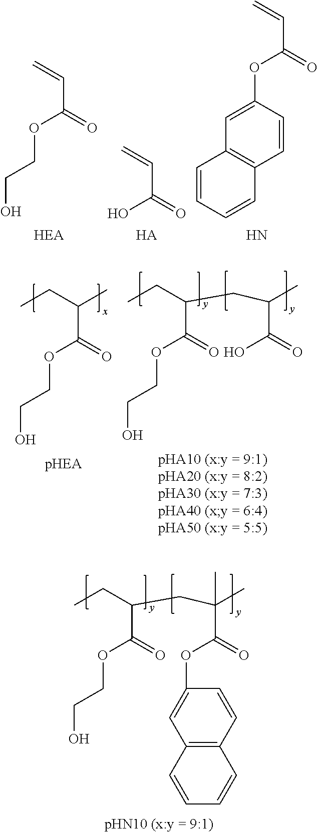

TABLE 2

| | | | | Weight | | |
|---|---|---|---|---|---|---|
| | | | | average | | |
| | | Monomer ratio | | molecular | | |
| | | (¹H-NMR) | | weight | | Tg |
| | Polymer | Monomer 1 | Monomer 2 | (Mw) | PDI | (° C.) |
| Synthesis Example 1 | pHEA | 100 | — | 3,642 | 1.82 | −18 |
| Synthesis Example 2 | pHA10 | 91 | 9 | 4,306 | 1.99 | −10 |
| Synthesis Example 3 | pHA20 | 82 | 18 | 5,338 | 2.11 | −3 |
| Synthesis Example 4 | pHA30 | 73 | 27 | 5,694 | 2.20 | 0 |
| Synthesis Example 5 | pHA40 | 64 | 36 | 6,572 | 2.31 | 7 |
| Synthesis Example 6 | pHA50 | 53 | 47 | 7,041 | 2.34 | 12 |
| Synthesis Example 7 | pHN10 | 93 | 7 | 50,883 | 5.1 | 2 |

### Comparative Synthesis Example 1: Synthesis of Polymer NP

Referring to KR2019-0057281 A, Polymer NP (pNP) having the following structure was synthesized. The weight average molecular weight of pNP may be 1,360, and the PDI of pNP was 1.2.

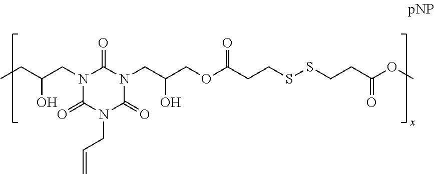

### Evaluation Example

The polymer shown Tables 3 and 4, pyridiniumtrifluoro methanesulfonate (acid generator), gallic acid monohydrate (additive), and R-43 (source: DIC, surfactant) were each dissolved to a concentration of 10 wt % in propylene glycol methyl ether (PGME), to prepare a stock solution. The prepared stock solutions were mixed in the amounts shown in Tables 3 and 4, and then 1.5 mL of PGME was added thereto to prepare a coating solution. The prepared coating solution was spin-coated at 1,500 rpm for 60 seconds on a silicon wafer on which TiN was deposited to a thickness of 7 nm. Following the spin coating, the silicon wafer was baked at 220° C. for 1 minute to form a thin film having a thickness of about 150 nm.

### (1) Evaluation of Etching Speed

Next, the thin film was etched for 0 to 6 seconds with H₂/N₂ plasma using a dry etching apparatus, Plasmalab 100 RIE (source: Oxford Instruments Plasma Technology) under the conditions of an output of 50 W and a pressure of 30 mtorr. Then, changes in the thickness of the thin film were observed. The etching speed was calculated from the changes in the thickness of the thin film, and is shown in Table 3.

TABLE 3

| | | | Acid | | | | |
|---|---|---|---|---|---|---|---|
| | | Polymer | generator | Additive | Surfactant | | |
| | | stock | stock | stock | stock | Ratio of | Etching |
| | | solution | solution | solution | solution | polymer:additive | speed |
| | Polymer | (mL) | (mL) | (mL) | (mL) | (weight ratio) | (nm/s) |
| Comparative | pNP | 1 | 0.05 | 0.05 | 0.04 | 1:0.05 | 9.3 |
| Example 1-1 | | | | | | | |
| Example 1-1 | pHEA | 1 | 0.05 | 0 | 0.04 | 1:0 | 10.32 |
| Example 1-2 | pHEA | 1 | 0.05 | 0.025 | 0.04 | 1:0.025 | 10.09 |
| Example 1-3 | pHEA | 1 | 0.05 | 0.05 | 0.04 | 1:0.05 | 9.81 |
| Example 1-4 | pHEA | 1 | 0.05 | 0.1 | 0.04 | 1:0.1 | 9.514 |
| Example 1-5 | pHA10 | 1 | 0.05 | 0.05 | 0.04 | 1:0.05 | 9.89 |
| Example 1-6 | pHA20 | 1 | 0.05 | 0.05 | 0.04 | 1:0.05 | 10.01 |
| Example 1-7 | pHA30 | 1 | 0.05 | 0.05 | 0.04 | 1:0.05 | 10.09 |
| Example 1-8 | pHA40 | 1 | 0.05 | 0.05 | 0.04 | 1:0.05 | 10.21 |
| Example 1-9 | pHA50 | 1 | 0.05 | 0.05 | 0.04 | 1:0.05 | 10.35 |
| Example 1-10 | pHN10 | 1 | 0.05 | 0.05 | 0.04 | 1:0.05 | 8.40 |

Referring to Table 3, it was confirmed that the polymer of Examples 1-1 to 1-9 had a faster etching speed than the polymer of Comparative Example 1-1. Also, it was confirmed that, depending on the amount of Monomer 2 including COOH, the etching speed of the polymer could be adjusted.

### (2) Evaluation of Wet Etching Resistance

Next, the thin film was immersed in a 20 wt % of aqueous hydrogen peroxide solution at 70° C. for 2 minutes and 30 seconds. Then, by confirming whether the thin film was peeled off from the TiN surface, the wet etching resistance was evaluated. In Table 4, cases where peeling off did not occur were indicated as Pass, and cases where peeling off occurred were indicated as Fail.

TABLE 4

| | | | Acid | | | | |
|---|---|---|---|---|---|---|---|
| | | Polymer | generator | Additive | Surfactant | | |
| | | Stock | Stock | Stock | Stock | Ratio of | Wet |
| | | solution | solution | solution | solution | polymer:additive | etching |
| | Polymer | (mL) | (mL) | (mL) | (mL) | (weight ratio) | resistance |
| Comparative | pNP | 1 | 0.05 | 0.043 | 0.04 | 1:0.05 | Fail |
| Example 2-1 | | | | | | | |
| Example 2-1 | pHEA | 1 | 0.05 | 0 | 0.04 | 1:0 | Pass |
| Example 2-2 | pHEA | 1 | 0.05 | 0.025 | 0.04 | 1:0.025 | Pass |
| Example 2-3 | pHEA | 1 | 0.05 | 0.05 | 0.04 | 1:0.05 | Pass |
| Example 2-4 | pHEA | 1 | 0.05 | 0.1 | 0.04 | 1:0.1 | Pass |
| Example 2-5 | pHA10 | 1 | 0.05 | 0 | 0.04 | 1:0 | Pass |
| Example 2-6 | pHA10 | 1 | 0.05 | 0.025 | 0.04 | 1:0.025 | Pass |
| Example 2-7 | pHA10 | 1 | 0.05 | 0.05 | 0.04 | 1:0.05 | Pass |
| Example 2-8 | pHA10 | 1 | 0.05 | 0.1 | 0.04 | 1:0.1 | Pass |
| Example 2-9 | pHA20 | 1 | 0.05 | 0 | 0.04 | 1:0 | Pass |
| Example 2-10 | pHA20 | 1 | 0.05 | 0.025 | 0.04 | 1:0.025 | Pass |
| Example 2-11 | pHA20 | 1 | 0.05 | 0.05 | 0.04 | 1:0.05 | Pass |
| Example 2-12 | pHA20 | 1 | 0.05 | 0.1 | 0.04 | 1:0.1 | Pass |
| Example 2-13 | pHA30 | 1 | 0.05 | 0 | 0.04 | 1:0 | Pass |
| Example 2-14 | pHA30 | 1 | 0.05 | 0.025 | 0.04 | 1:0.025 | Pass |
| Example 2-15 | pHA30 | 1 | 0.05 | 0.05 | 0.04 | 1:0.05 | Pass |
| Example 2-16 | pHA30 | 1 | 0.05 | 0.1 | 0.04 | 1:0.1 | Pass |
| Example 2-17 | pHA40 | 1 | 0.05 | 0 | 0.04 | 1:0 | Pass |
| Example 2-18 | pHA40 | 1 | 0.05 | 0.025 | 0.04 | 1:0.025 | Pass |
| Example 2-19 | pHA40 | 1 | 0.05 | 0.05 | 0.04 | 1:0.05 | Pass |
| Example 2-20 | pHA40 | 1 | 0.05 | 0.1 | 0.04 | 1:0.1 | Pass |
| Example 2-21 | pHA50 | 1 | 0.05 | 0 | 0.04 | 1:0 | Pass |
| Example 2-22 | pHA50 | 1 | 0.05 | 0.025 | 0.04 | 1:0.025 | Pass |
| Example 2-23 | pHA50 | 1 | 0.05 | 0.05 | 0.04 | 1:0.05 | Pass |
| Example 2-24 | pHA50 | 1 | 0.05 | 0.1 | 0.04 | 1:0.1 | Pass |
| Example 2-25 | pHN10 | 1 | 0.05 | 0 | 0.04 | 1:0 | Pass |
| Example 2-26 | pHN10 | 1 | 0.05 | 0.025 | 0.04 | 1:0.025 | Pass |
| Example 2-27 | pHN10 | 1 | 0.05 | 0.05 | 0.04 | 1:0.05 | Pass |
| Example 2-28 | pHN10 | 1 | 0.05 | 0.1 | 0.04 | 1:0.1 | Pass |

Referring to Table 4, it was confirmed that all of Examples 2-1 to 2-28 were capable of providing thin films with etching resistance to an aqueous hydrogen peroxide solution. In particular, referring to Examples 2-1, 2-5, 2-9, 2-13, 2-17, 2-21, and 2-25, it was confirmed that use of the polymers of the disclosure were able to provide thin films with etching resistance to an aqueous hydrogen peroxide solution even without using an additive.

According to the one or more embodiments, provided are a polymer having improved resistance to wet etching, improved etching speed for dry etching, and/or improved gap-fill properties, a polymer-containing composition including the polymer, and a method of forming a pattern by using the polymer-containing composition.

It should be understood that the example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A polymer comprising a first repeating unit represented by Formula 1 and having a glass transition temperature of 50° C. or less: 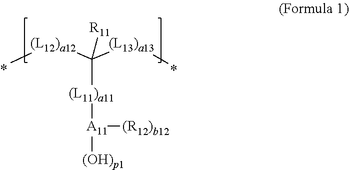
wherein, in Formula 1,
L₁₁ to L₁₃ are each independently a single bond; O; S; C(═O); C(═O)O; OC(═O); C(═O)NH; NHC(═O); or a linear, branched, or cyclic C₁-C₃₀ divalent hydrocarbon group that optionally includes a heteroatom,
a11 to a13 are each independently an integer from 1 to 4,
A₁₁ is a linear, branched, or cyclic C₁-C₃₀ alkyl group that optionally includes a heteroatom; or a linear, branched, or cyclic C₁-C₃₀ alkenyl group that optionally includes a heteroatom,
R₁₁ and R₁₂ are each independently hydrogen; deuterium; a halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group that optionally includes a heteroatom,
b12 is an integer from 1 to 10,
p1 is an integer from 1 to 5, and
* indicates a binding site to a neighboring atom.

2. The polymer of claim 1, wherein the glass transition temperature of the polymer is 25° C. or less.

3. The polymer of claim 1, wherein L₁₁ to L₁₃ are each independently a single bond; O; S; C(═O); C(═O)O; OC(═O); C(═O)NH; NHC(═O); a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

4. The polymer of claim 1, wherein
L₁₁ is a single bond; O; C(═O); C(═O)O; or OC(═O), and
L₁₂ and L₁₃ are each independently a single bond; O; C(═O); C(═O)O; OC(═O); and a C₁-C₂₀ alkylene group unsubstituted or substituted with deuterium, a halogen, a C₁-C₂₀ alkyl group, a C₁-C₂₀ halogenated alkyl group, a C₁-C₂₀ alkoxy group, a phenyl group, a naphthyl group, or a combination thereof.

5. The polymer of claim 1, wherein A₁₁ is a linear, branched, or cyclic C₁-C₃₀ alkyl group that optionally includes a heteroatom.

6. The polymer of claim 1, wherein A₁₁ is selected from groups represented by Formulae 9-1 to 9-37 and 10-1 to 10-48, groups in which at least one carbon of one of the groups represented by Formulae 9-1 to 9-37 and 10-1 to 10-48 is substituted with oxygen, or groups in which at least one carbon of one of the groups represented by Formulae 9-1 to 9-37 and 10-1 to 10-48 is substituted with a carbonyl group 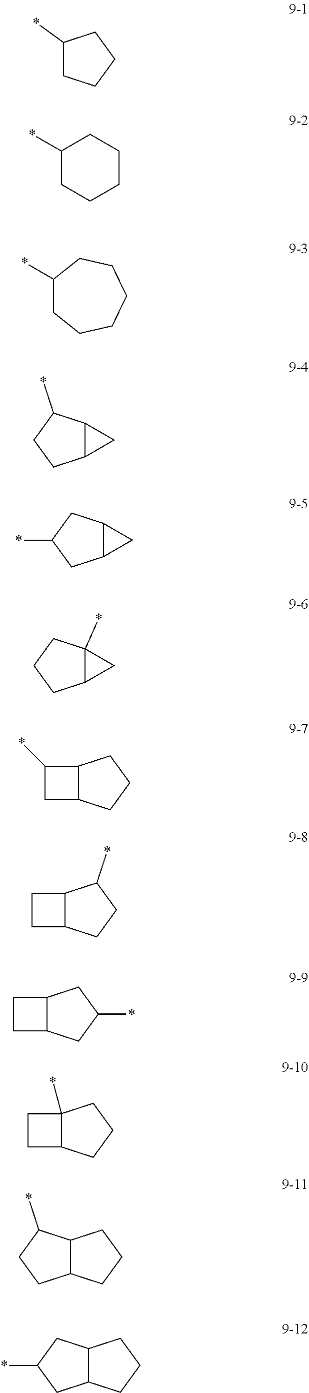 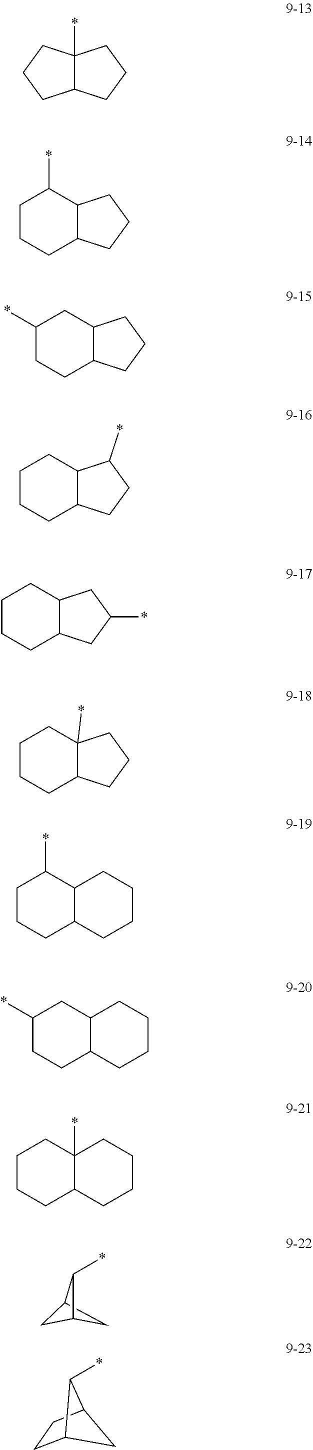 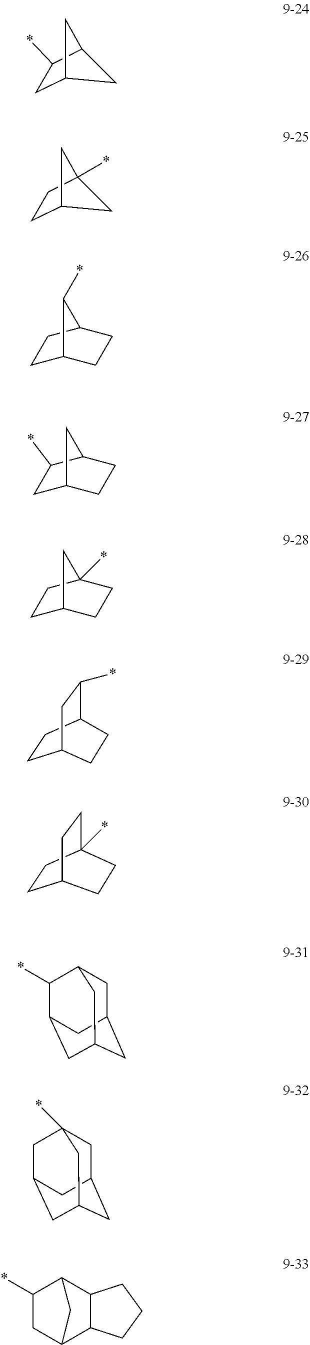 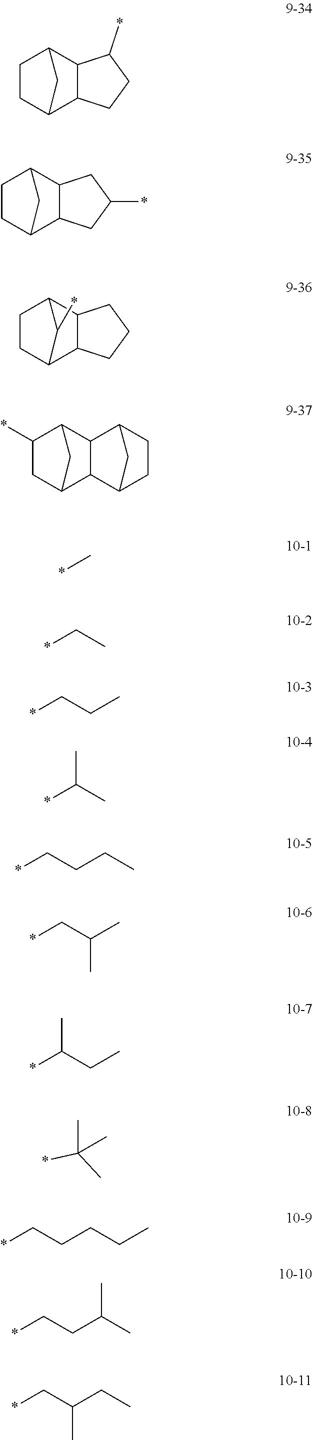 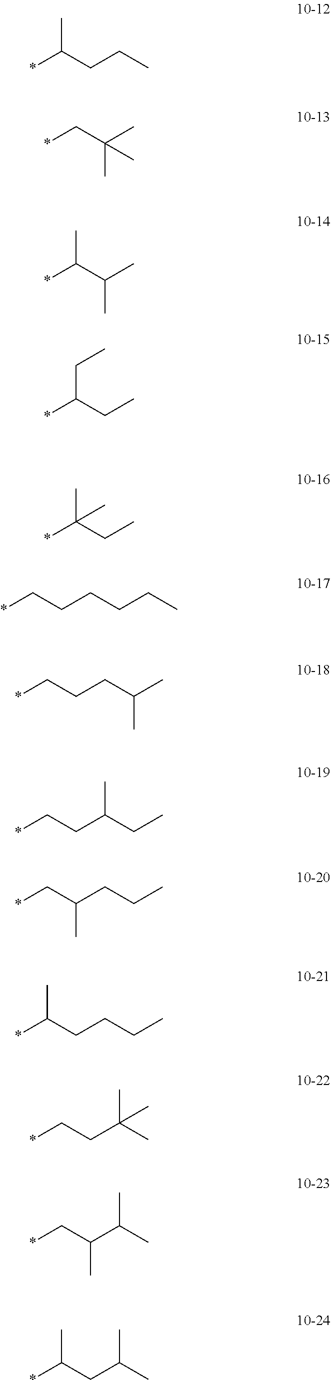 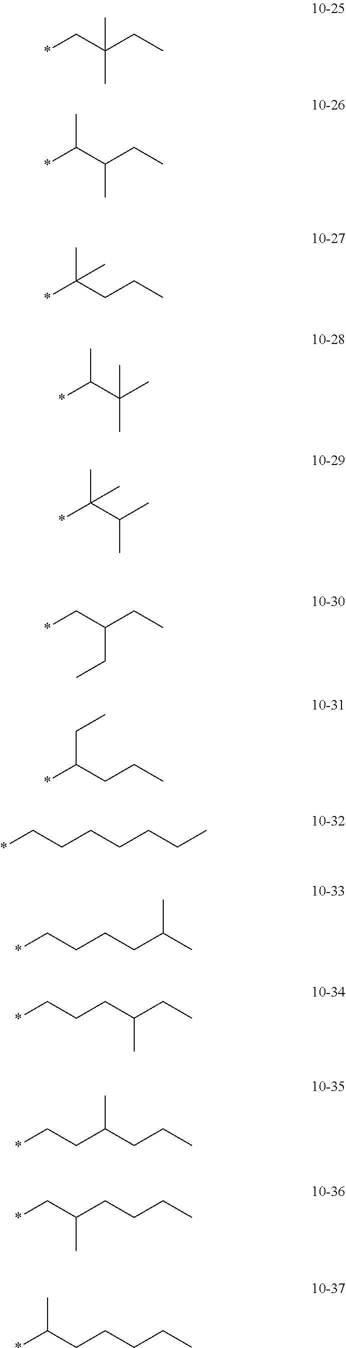 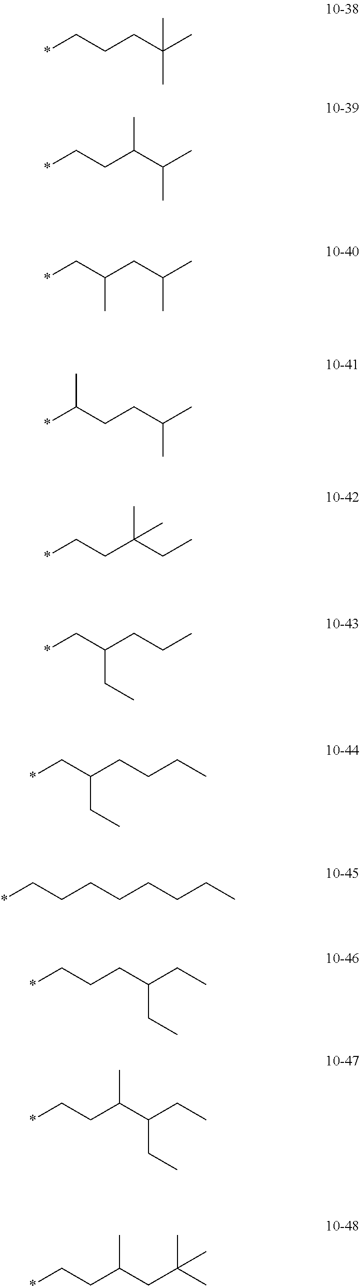
wherein, in Formulae 9-1 to 9-37 and 10-1 to 10-48,
* indicates a binding site to L₁₁.

7. The polymer of claim 1, wherein
A₁₁ is selected from groups represented by Formulae 10-1 to 10-48: 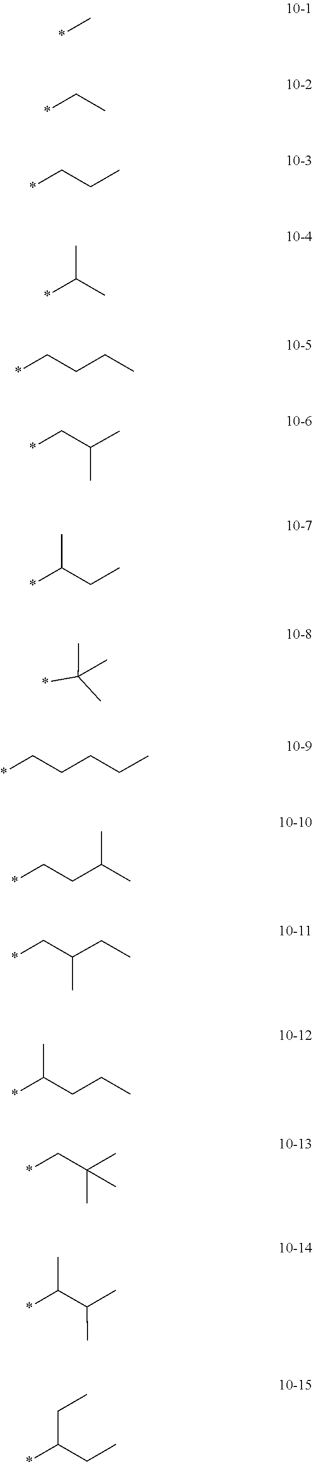 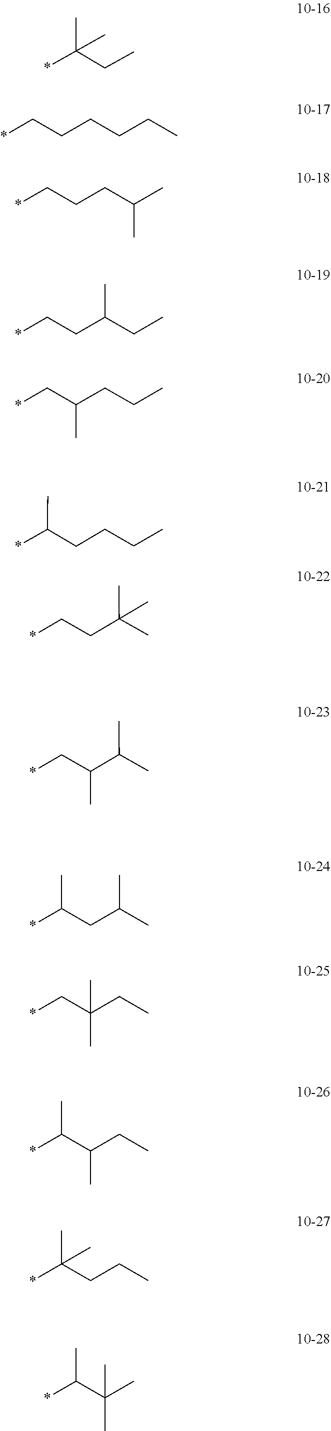 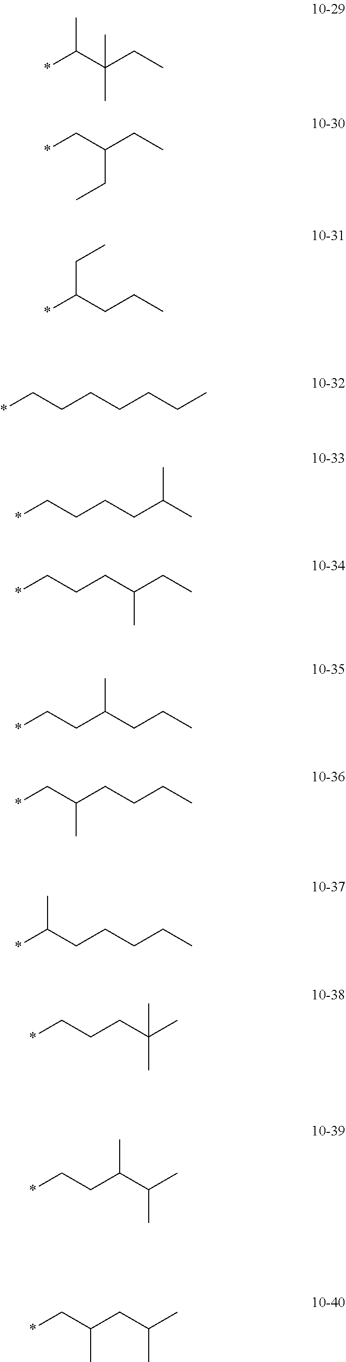 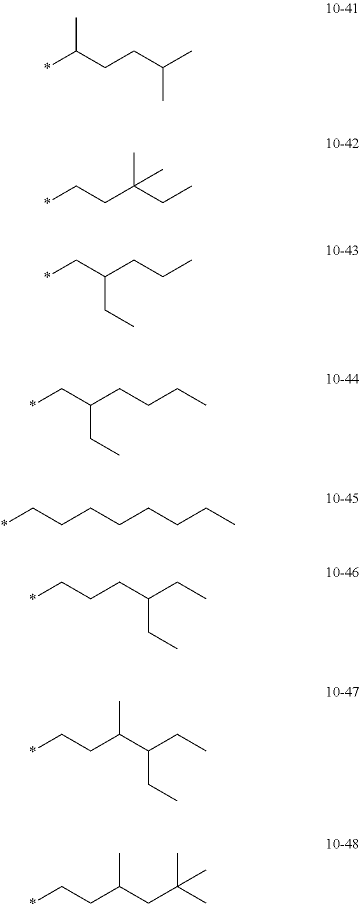
wherein, in Formulae 10-1 to 10-48,
* indicates a binding site to L₁₁.

8. The polymer of claim 1, wherein R₁₁ and R₁₂ are each independently hydrogen; deuterium; a halogen; a cyano group; a hydroxy group; an amino group; a carboxylic acid group; a thiol group; and a C₁-C₂₀ alkyl group, a C₃-C₂₀ cycloalkyl group, or a C₆-C₂₀ aryl group, each unsubstituted or substituted with deuterium, a halogen, a cyano group, a hydroxy group, an amino group, a carboxylic acid group, a thiol group, an ester moiety, a sulfonate ester moiety, a carbonate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or a combination thereof.

9. The polymer of claim 1, wherein the first repeating unit is represented by Formula 1-1: 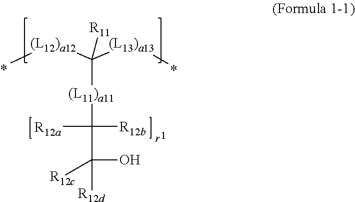
wherein, in Formula 1-1,
r1 is an integer from 1 to 3,
R₁₂ₐ to R_{12d} are each independently hydrogen; deuterium; a halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group that optionally includes a heteroatom, and
* indicates a binding site to a neighboring atom.

10. The polymer of claim 1, wherein the first repeating unit is selected from Group I:

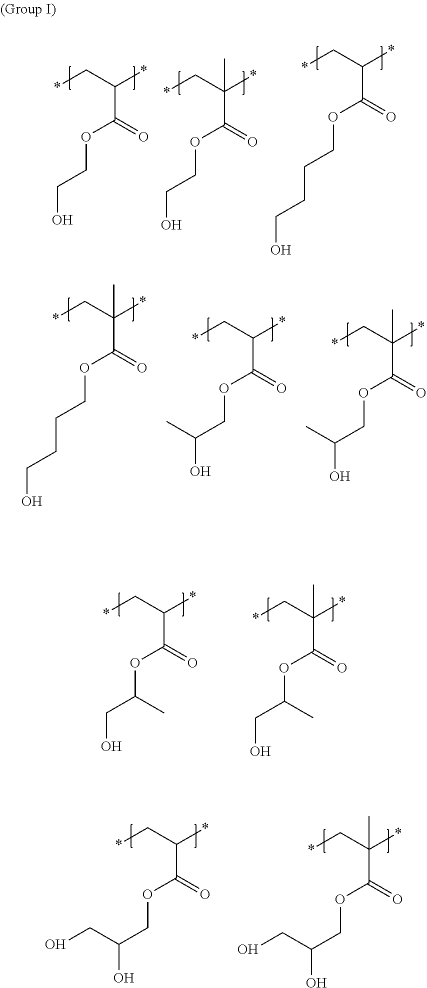

11. The polymer of claim 1, further comprising at least one of a second repeating unit represented by Formula 2 or a third repeating unit represented by Formula 3: 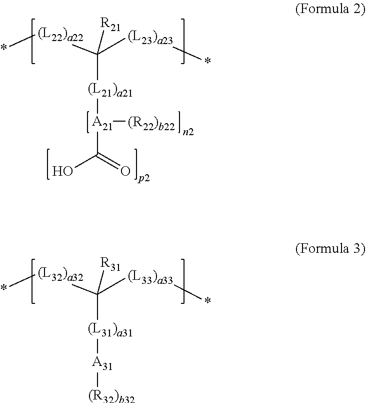
wherein, in Formulae 2 and 3,
L₂₁ to L₂₃ and L₃₁ to L₃₃ are each independently a single bond; O; S; C(═O); C(═O)O; OC(═O); C(═O)NH; NHC(═O); or a linear, branched, or cyclic C₁-C₃₀ divalent hydrocarbon group that optionally includes a heteroatom,
a21 to a23 and a31 to a33 are each independently an integer from 1 to 4,
A₂₁ and A₃₁ are each independently a linear, branched, or cyclic C₁-C₃₀ alkyl group that optionally includes a heteroatom; a linear, branched, or cyclic C₁-C₃₀ alkenyl group that optionally includes a heteroatom; or a C₁-C₃₀ aromatic group that optionally includes a heteroatom,
n2 is 0 or 1,
R₂₁, R₂₂, R₃₁, and R₃₂ are each independently hydrogen; deuterium; a halogen; a cyano group; a hydroxy group; an amino group; a carboxylic acid group; a thiol group; an ester moiety; a sulfonate ester moiety; a carbonate moiety; a lactone moiety; a sultone moiety; a carboxylic anhydride moiety; or a linear, branched, or cyclic C₁-C₃₀ monovalent hydrocarbon group that optionally includes a heteroatom,
b22 and b32 are each independently an integer from 1 to 10,
p2 is an integer from 1 to 5, and
* indicates a binding site to a neighboring atom.

12. The polymer of claim 11, wherein A₂₁ and A₃₁ are each independently a linear, branched, or cyclic C₁-C₃₀ alkyl group that optionally includes a heteroatom; or a C₁-C₃₀ aromatic group that optionally includes a heteroatom.

13. The polymer of claim 11, wherein A₂₁ and A₃₁ are each independently selected from groups represented by Formulae 9-1 to 9-37 and 10-1 to 10-48, groups in which at least one carbon of one of the groups represented by Formulae 9-1 to 9-37 and 10-1 to 10-48 is substituted with oxygen, or groups in which at least one carbon of one of the groups represented by Formulae 9-1 to 9-37 and 10-1 to 10-48 is substituted with a carbonyl group, a benzene group, a naphthalene group, a phenanthrene group, and an anthracene group 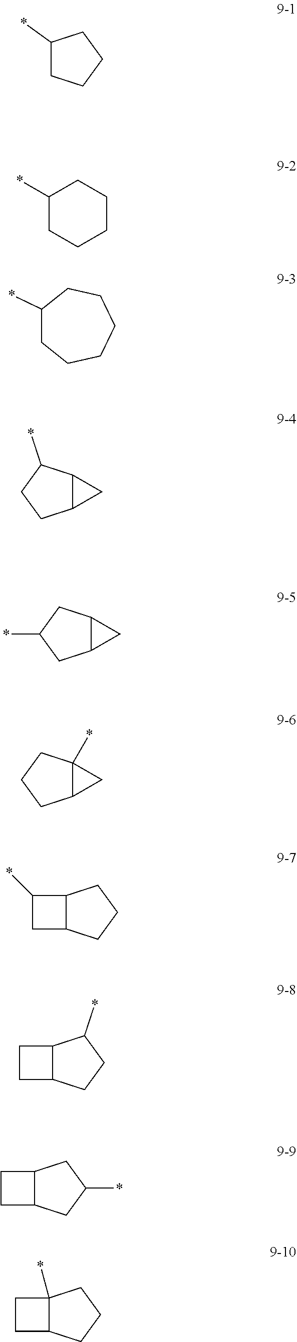 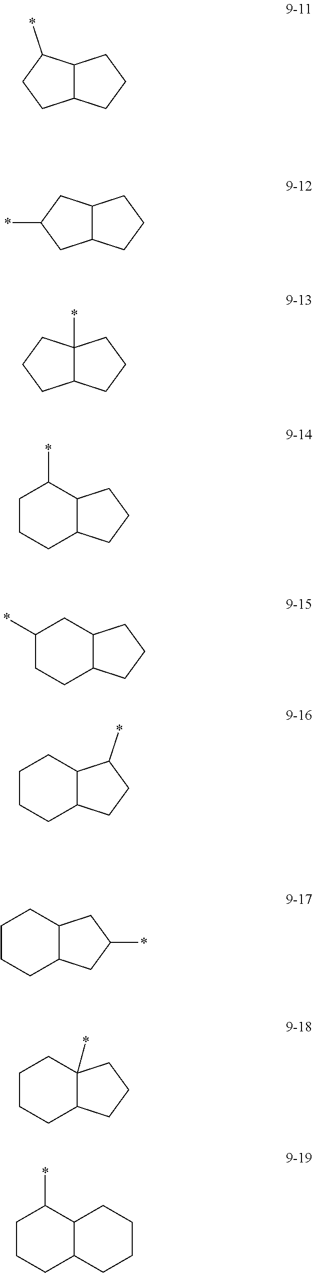 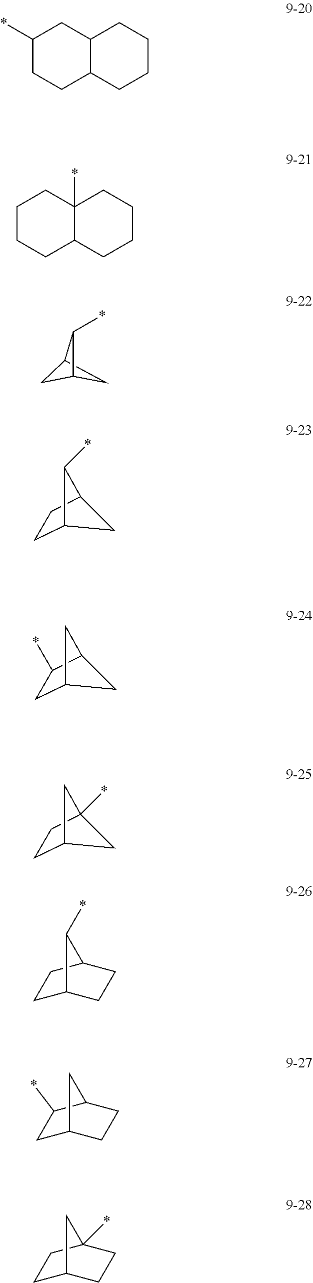 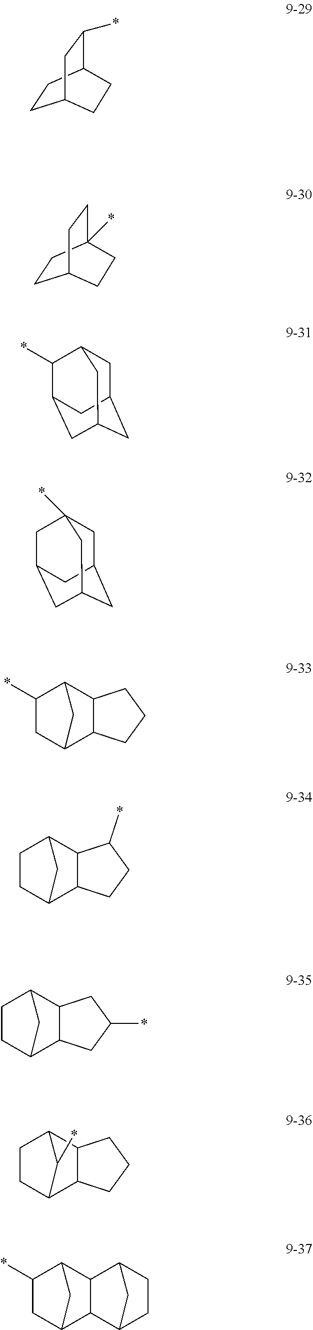 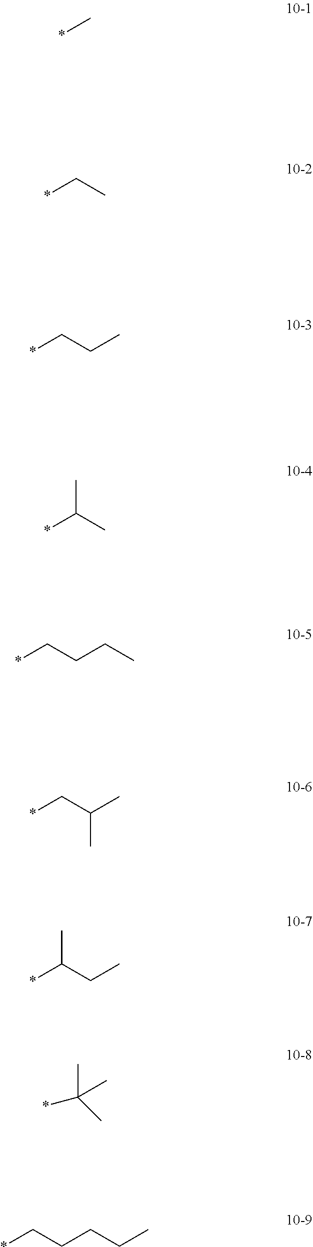 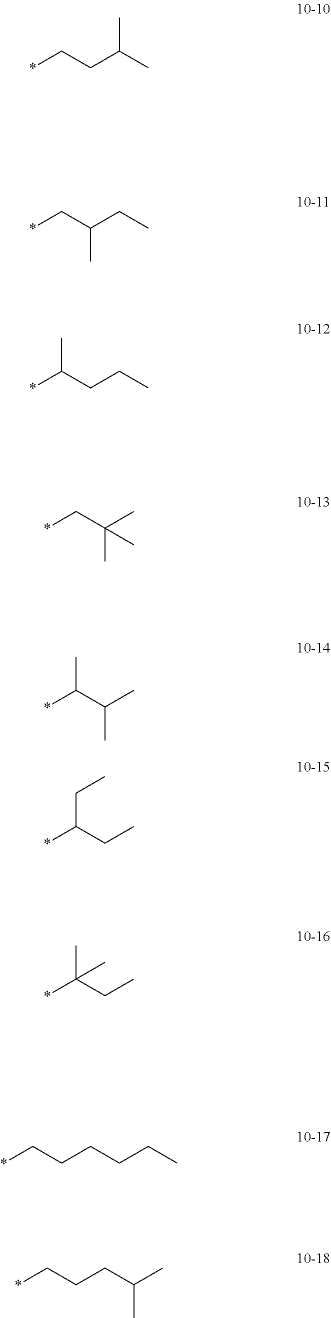 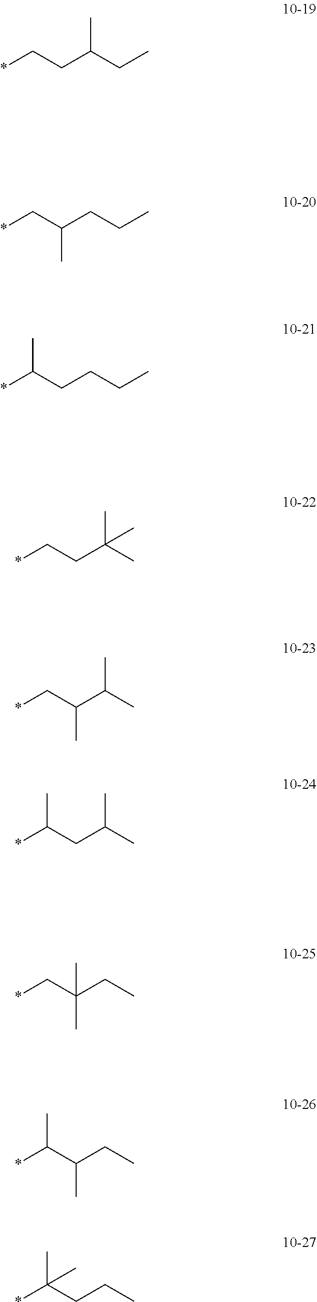 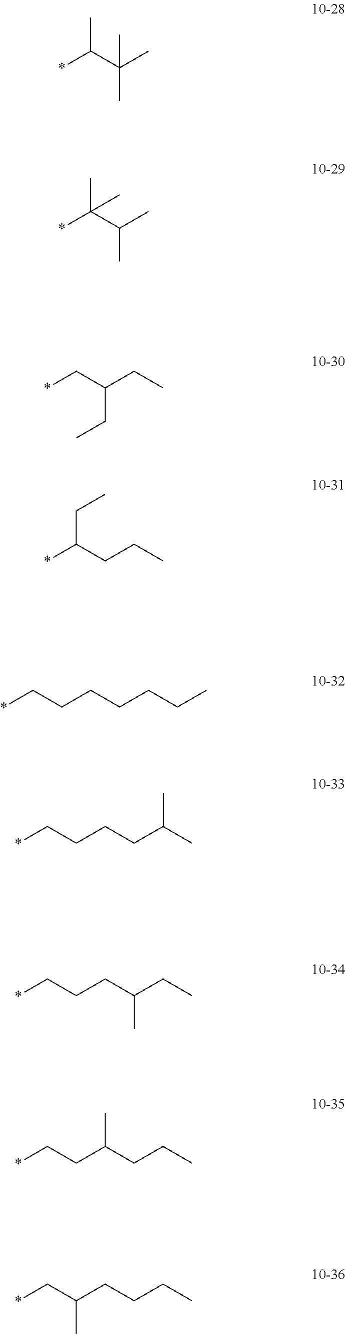 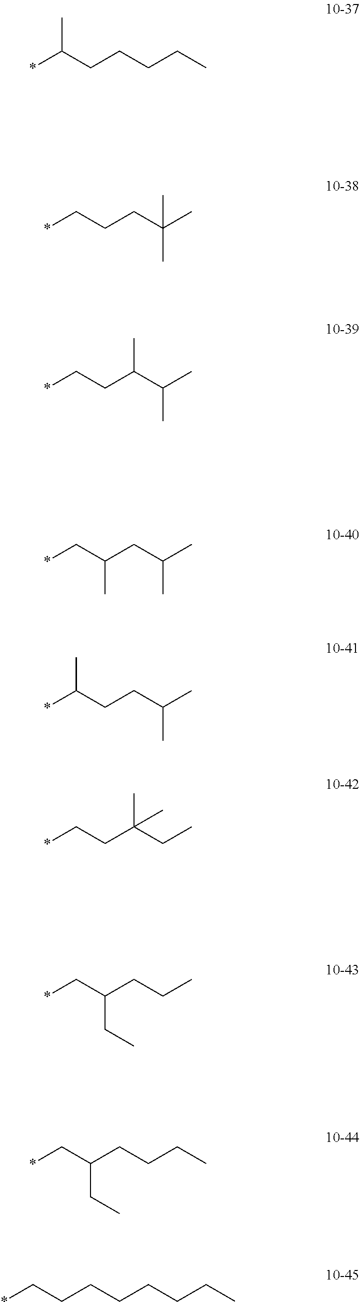 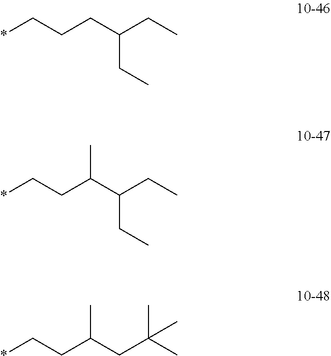
wherein, in Formulae 9-1 to 9-37 and 10-1 to 10-48,
* indicates a binding site to L₂₁ or L₃₁.

14. The polymer of claim 11, wherein R₃₂ is a linear, branched, or cyclic C₁-C₃₀ monovalent hydrocarbon group that optionally includes a heteroatom.

15. The polymer of claim 11, wherein
the second repeating unit is at least one of Group II, and
the third repeating unit is at least one of from Group III, and

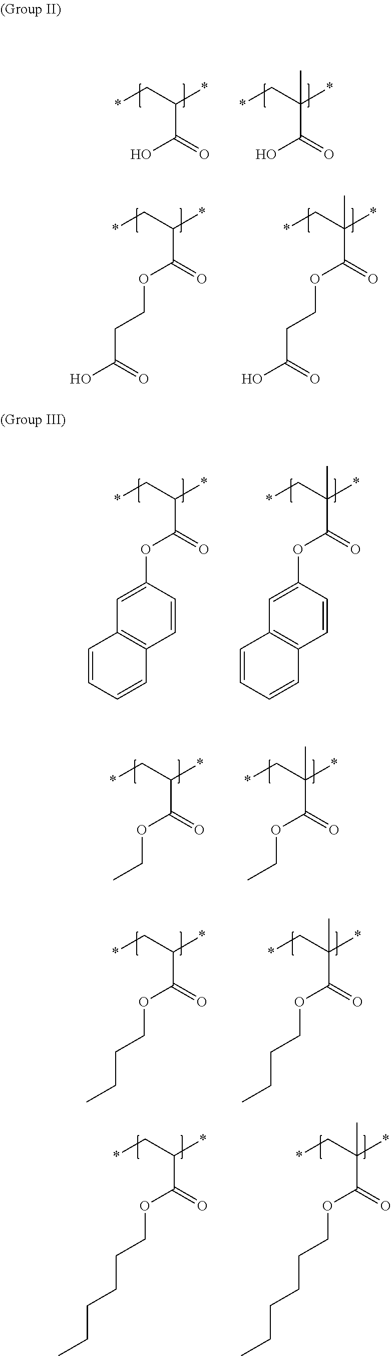

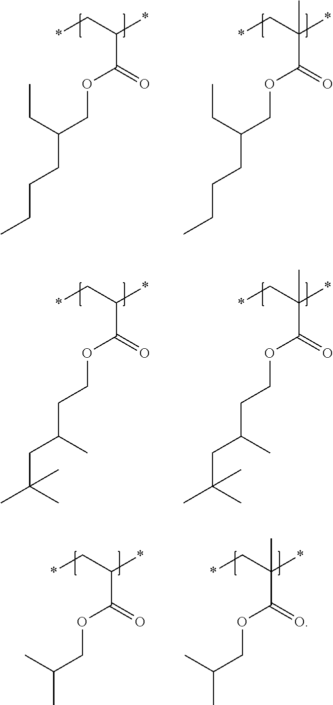

16. A polymer-containing composition comprising:
the polymer of claim 1;
an acid generator; and
an organic solvent.

17. The polymer-containing composition of claim 16, wherein the acid generator comprises p-toluenesulfonic acid, trifluoromethanesulfonic acid, pyridinium-p-toluenesulfonate, pyridinium trifluoromethanesulfonate, salicylic acid, 5-sulfosalicylic acid, camphorsulfonic acid, 4-chlorobenzenesulfonic acid, 4-phenolsulfonic acid, 4-phenolsulfonic acidmethyl, benzenedisulfonic acid, 1-naphthalenesulfonic acid, citric acid, benzoic acid, hydroxybenzoic acid, or a combination thereof.

18. A method of forming a pattern, the method comprising:
forming an insulating layer by applying the polymer-containing composition of claim 16 onto a substrate provided with a first layer;
forming an insulating pattern such that a first surface of the first layer is exposed by selectively removing one or more portions of the insulating layer; and
removing the first layer having the exposed first surface.

19. The method of claim 18, wherein the first layer comprises a conductive metal oxide, a conductive metal oxynitride, a conductive metal nitride, or a combination thereof.

20. The method of claim 18, wherein
the removing of the first layer having the exposed first surface includes a wet etching process, and
the wet etching process uses an etchant containing hydrogen peroxide.
